(19) United States
(12) Patent Application Publication
(10) Pub. No.: US 2024/0364078 A1
(43) Pub. Date: Oct. 31, 2024

(54) TRANSVERSE MULTIMODE SEMICONDUCTOR LASER ELEMENT

(71) Applicant: NICHIA CORPORATION, Anan-shi (JP)

(72) Inventor: Hisashi OGAWA, Yokohama-shi (JP)

(73) Assignee: NICHIA CORPORATION, Anan-shi (JP)

(21) Appl. No.: 18/648,297

(22) Filed: Apr. 26, 2024

(30) Foreign Application Priority Data
Apr. 28, 2023 (JP) 2023-074037
Apr. 11, 2024 (JP) 2024-064083

(51) Int. Cl. H01S 5/12; H01S 5/22

(52) U.S. Cl. CPC H01S 5/12; H01S 5/22; H01S 2301/166

(57) ABSTRACT

A transverse multimode semiconductor laser element includes: a semiconductor layered portion that includes an active layer and has a waveguide structure, wherein the semiconductor layered portion includes: a first region that includes a first diffraction grating and has a refractive index n₁, and a second region that includes a first core region having a refractive index n₂₁ and a plurality of first cladding regions having a refractive index n₂₂ respectively provided on opposite sides of the first core region, and allows a laser beam to propagate in a plurality of transverse modes. The laser beam emitted from the second region propagates through the first region at a maximum diffusion angle θₘₐₓ₁ determined by the refractive index n₁, the refractive index n₂₁, and the refractive index n₂₂.

### CROSS REFERENCE TO RELATED APPLICATION

This application claims priority to Japanese Patent Application No. 2023-074037, filed on Apr. 28, 2023, and Japanese Patent Application No. 2024-064083, filed on Apr. 11, 2024, the entire contents of which are hereby incorporated by reference.

### BACKGROUND

The present disclosure relates to a transverse multimode semiconductor laser element.

An increase in output of a laser beam of a semiconductor laser element has been required. High-output semiconductor laser elements have come to be used, for example, as light sources for machining. Therefore, it is conceivable to use a transverse multimode semiconductor laser element that can easily obtain higher output than a lateral single mode semiconductor laser element. For example, Japanese Patent Publication No. JP 2011-151238 A discloses a transverse multimode semiconductor laser element.

### SUMMARY

However, in the transverse multimode semiconductor laser element disclosed in Japanese Patent Publication No. JP 2011-151238 A, because the oscillation wavelength is different for each transverse mode, the full width at half maximum of a spectral linewidth of the emitted laser beam becomes large, and it is difficult to efficiently obtain high output.

The object of the present disclosure is to provide a transverse multimode semiconductor laser element having a small variation in oscillation wavelength for each transverse mode.

According to one embodiment of the present disclosure, a transverse multimode semiconductor laser element according to an embodiment of the present disclosure comprises: a semiconductor layered portion including an active layer and having a waveguide structure. The semiconductor layered portion includes: a first region that includes a first diffraction grating and has a refractive index n₁, and a second region that includes a first core region having a refractive index n₂₁ and a first cladding region having a refractive index n₂₂ provided on opposite sides of the first core region, and propagates a laser beam in a plurality of transverse modes. The laser beam emitted from the second region propagates through the first region at a maximum diffusion angle θₘₐₓ₁ determined by the refractive index n₁, the refractive index n₂₁, and the refractive index n₂₂. In a cross section perpendicular to an optical axis of the laser beam, opposite end portions of the first region in a direction perpendicular to a stacking direction of the semiconductor layered portion are each located outside a virtual line extending at the maximum diffusion angle θₘₐₓ₁ from opposite ends of an emission end face of the first core region on the first region side.

In addition, according to another embodiment of the present disclosure, a transverse multimode semiconductor laser element according to an embodiment of the present disclosure comprises: a semiconductor layered portion comprising the active layer. The semiconductor layered portion includes: a first region including a first diffraction grating, and a second region having a transverse multimode waveguide. The first region has a first end face that emits the laser beam. In a cross-sectional view orthogonal to a periodic direction of the diffraction grating, in a direction orthogonal to a stacking direction of the semiconductor layered portion, a width of the first end face is larger than a beam diameter of the laser beam; In top view, in a direction orthogonal to a periodic direction of the diffraction grating, the first region also expands in a direction away from a center of the laser beam with respect to a shorter line among lines connecting an end of the beam having the beam diameter and a first vertex that is a boundary between the first region and a first core region of the transverse multimode waveguide.

The semiconductor laser element according to certain embodiments of the present disclosure can provide a transverse multimode semiconductor laser element having a small variation in oscillation wavelength for each transverse mode.

### BRIEF DESCRIPTION OF THE DRAWINGS

FIG. 1 is a schematic diagram illustrating a waveguide structure of a semiconductor laser element according to a first embodiment of the present disclosure;

FIG. 2 is a top view of the semiconductor laser element according to the first embodiment;

FIG. 3A is a schematic cross-sectional view taken along line III-III of the semiconductor laser element illustrated in FIG. 2;

FIG. 3B is a schematic cross-sectional view taken along line III-III of another embodiment of the semiconductor laser element illustrated in FIG. 2;

FIG. 4 is a schematic cross-sectional view taken along line IV-IV of the semiconductor laser element illustrated in FIG. 2;

FIG. 5 is a schematic cross-sectional view taken along line V-V of the semiconductor laser element illustrated in FIG. 2;

FIG. 6A is a graph illustrating a relationship between a transverse mode order and an equivalent refractive index;

FIG. 6B is a graph illustrating a relationship between a transverse mode order and a Bragg wavelength;

FIG. 7 is a diagram illustrating an outline of a method of measuring a beam waist radius W₀ and a beam divergence angle φ;

FIG. 8 is a schematic diagram illustrating another mode of the semiconductor laser element according to the first embodiment;

FIG. 9 is a schematic diagram illustrating another mode of the semiconductor laser element according to the first embodiment;

FIG. 10 is a schematic view illustrating another mode of the semiconductor laser element of the first embodiment;

FIG. 11A is a schematic view illustrating another mode of the semiconductor laser element according to the first embodiment;

FIG. 11B is a schematic view illustrating another mode of the semiconductor laser element according to the first embodiment;

FIG. 12 is a schematic cross-sectional view illustrating one step in the method for manufacturing the semiconductor laser element according to the first embodiment;

FIG. 13 is a schematic cross-sectional view illustrating one step in the method for manufacturing the semiconductor laser element according to the first embodiment;

FIG. 14 is a schematic cross-sectional view illustrating one step in the method for manufacturing the semiconductor laser element according to the first embodiment;

FIG. 15 is a schematic cross-sectional view illustrating one step in the method for manufacturing the semiconductor laser element according to the first embodiment;

FIG. 16 is a schematic top view illustrating one step in the method for manufacturing the semiconductor laser element according to the first embodiment;

FIG. 17 is a schematic cross-sectional view illustrating one step in the method for manufacturing the semiconductor laser element according to the first embodiment;

FIG. 18 is a schematic top view of a semiconductor laser element according to a first modification of the first embodiment;

FIG. 19 is a schematic top view of a semiconductor laser element according to a second modification of the first embodiment;

FIG. 20 is a schematic diagram illustrating a configuration of a wavelength beam coupling device according to the third embodiment of the present disclosure;

FIG. 21A is a graph showing intensity of a laser beam output from the semiconductor laser element of Example 1 when a current of 12A is injected; and

FIG. 21B is a graph showing the intensity of a laser beam output from the semiconductor laser element of Comparative Example 1 when a current of 12A is injected.

### DETAILED DESCRIPTION

Hereinafter, embodiments, modifications, and examples for carrying out the invention according to the present disclosure will be described with reference to the drawings. Note that the semiconductor laser element according to the present disclosure described below is for embodying the technical idea of the invention according to the present disclosure, and the invention according to the present disclosure is not limited to the following unless otherwise specified.

In the drawings, members having the same function may be denoted by the same reference numerals. In consideration of the description of the main points or ease of understanding, embodiments, modifications, or examples may be shown separately for convenience, but partial replacement or combination of configurations shown in different embodiments, modifications, and examples is possible. In the following embodiments, modifications, and examples, descriptions of matters common to the above will be omitted, and only different points will be described. In particular, the same operation and effect by the same configuration will not be sequentially mentioned for each embodiment, modification, and example. The sizes, positional relationships, and the like of the members illustrated in the drawings may be exaggerated for clarity of description.

In the following description, in order to simplify the description, the transverse multimode semiconductor laser element is also simply referred to as a semiconductor laser element.

### First Embodiment

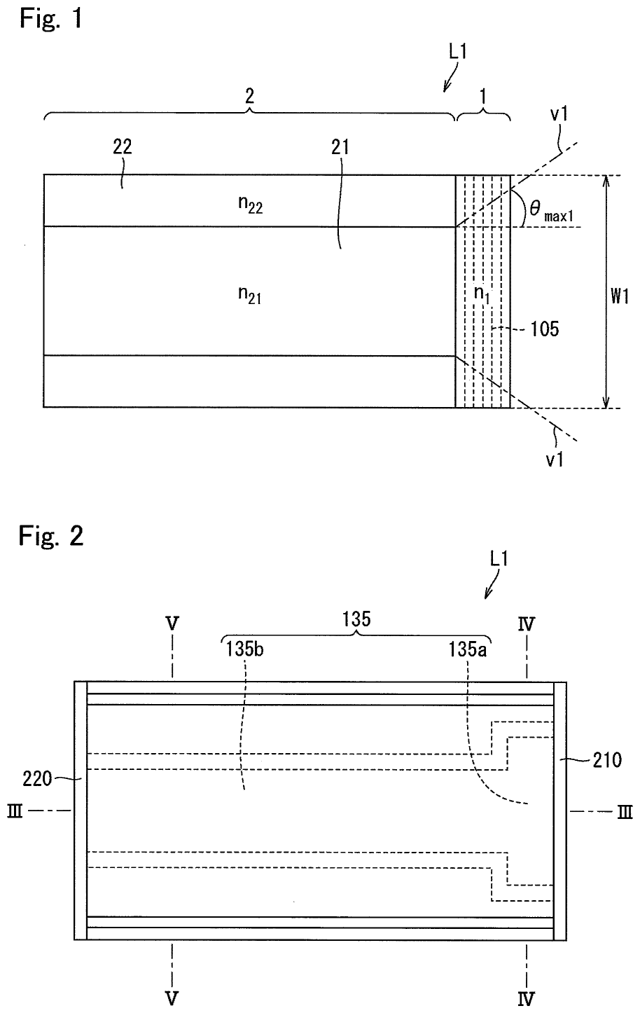

The semiconductor laser element according to the first embodiment is a semiconductor laser element L1 including a semiconductor layered portion including an active layer and having a waveguide structure illustrated in FIG. 1. Here, FIG. 1 is a schematic diagram illustrating a waveguide structure in a semiconductor laser element L1 according to the first embodiment.

Specifically, as illustrated in FIG. 1, the semiconductor layered portion in the semiconductor laser element L1 of the first embodiment includes (i) a first region 1 that includes a first diffraction grating 105 and has a refractive index n₁, and (ii) a second region 2 that includes a first core region 21 having a refractive index n₂₁ and first cladding regions 22 having a refractive index n₂₂ respectively provided on opposite sides of the first core region 21, and allows a laser beam to propagate in a plurality of transverse modes.

In the semiconductor laser element L1 including the first region 1 and the second region 2 configured as described above, the laser beam emitted from the second region 2 propagates through the first region 1 at the maximum diffusion angle θₘₐₓ₁ determined by the refractive index n₁, the refractive index n₂₁, and the refractive index n₂₂.

In the semiconductor laser element L1 according to the first embodiment, the width of the first region 1 is set in consideration of the maximum diffusion angle θₘₐₓ₁ of the laser beam emitted from the second region 2 and incident on the first region 1.

Specifically, in a cross section perpendicular to an optical axis of the laser beam, the width W1 of the first region 1 is set such that opposite end portions of the first region 1 in a direction perpendicular to a stacking direction of the semiconductor layered portion are located outside virtual lines v1 each extending at the maximum diffusion angle θₘₐₓ₁ from corresponding one of opposite ends of an emission end face (a first emission end face) of the first core region 21 on the first region 1 side.

In the present specification, the refractive index n₂₁ and the refractive index n₂₂ each refer to an effective refractive index in consideration of optical confinement in the stacking direction of the semiconductor layered portion. The refractive index n₁ is an effective refractive index obtained by averaging the modulation of the refractive index of the diffraction grating in consideration of optical confinement in the stacking direction of the semiconductor layered portion. The maximum diffusion angle θₘₐₓ₁ is equal to the maximum light receiving angle of the optical waveguide in the second region 2.

Hereinafter, a semiconductor laser element L1 according to the first embodiment will be described in detail with reference to the drawings.

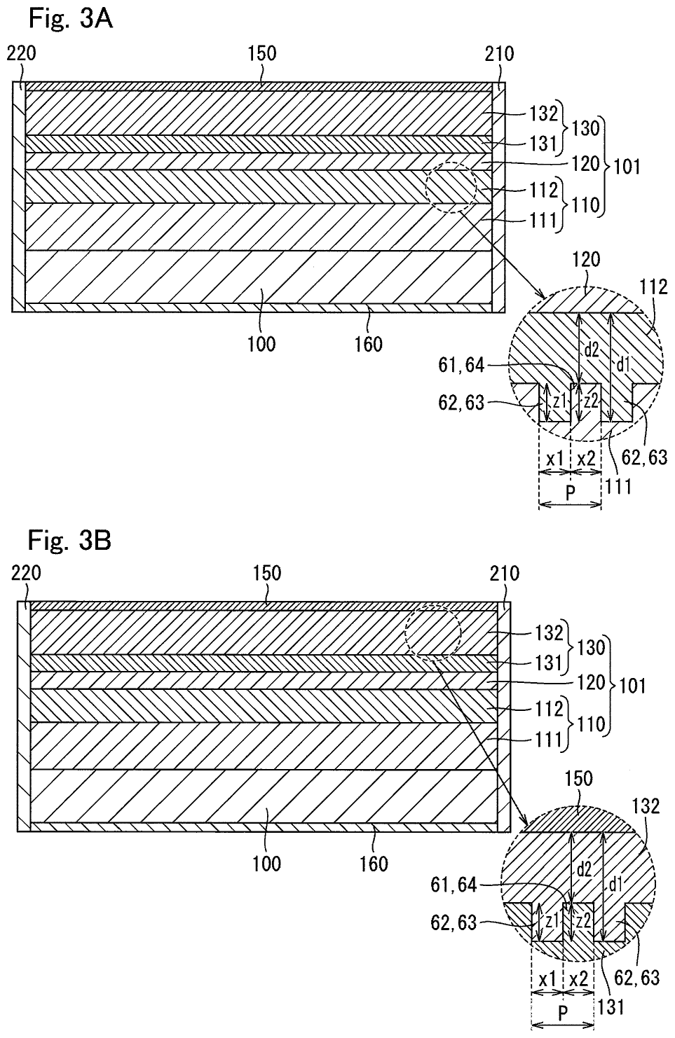

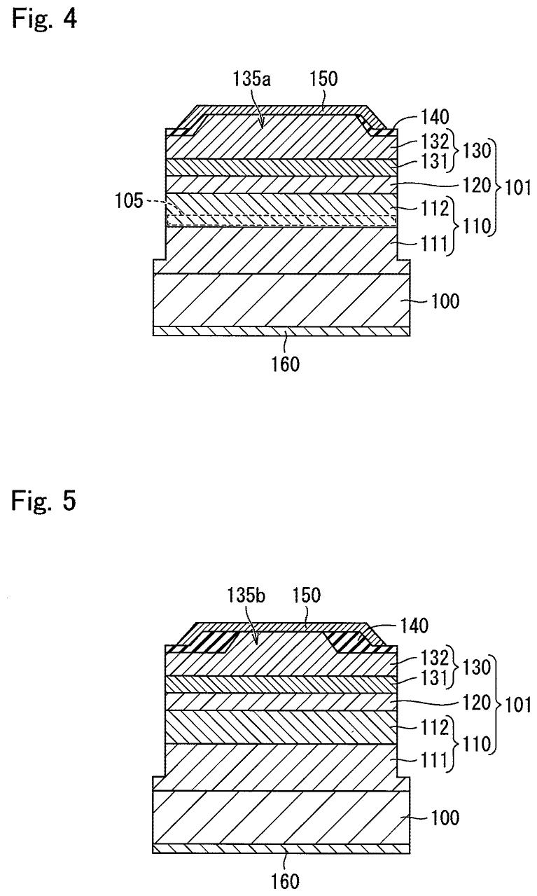

FIG. 2 is a top view of the semiconductor laser element L1 according to the first embodiment, FIG. 3A is a schematic cross-sectional view taken along line III-III of FIG. 2, FIG. 4 is a schematic cross-sectional view taken along line IV-IV of FIG. 2, and FIG. 5 is a schematic cross-sectional view taken along line V-V of FIG. 2.

The semiconductor laser element L1 according to the first embodiment of the present disclosure includes a semiconductor layered portion 101 provided on a substrate 100. As illustrated in FIGS. 3A to 5, for example, the semiconductor layered portion 101 may include
(a) an n-side semiconductor layer 110 including an n-side cladding layer 111 and an n-side light guide layer 112;
(b) an active layer 120 provided on the n-side semiconductor layer 110;
(c) a p-side semiconductor layer 130 provided on the active layer 120 and including a p-side light guide layer 131 and a p-side cladding layer 132.

The semiconductor layered portion 101 includes a ridge 135 provided in the p-side cladding layer 132. The ridge 135 includes a first ridge 135a provided in the first region 1 and a second ridge 135b provided in the second region 2, and for example, the first ridge 135a and the second ridge 135b are provided so that the center lines in the traveling direction of the laser beam coincide with each other.

The first electrode 150 is provided on the semiconductor layered portion 101 so as to be in contact with the upper surface of the ridge 135. For example, the insulating layer 140 is provided on the upper surface of the p-side cladding layer 132 except for the upper surface of the ridge 135, and the first electrode 150 is provided so as to be in contact with the upper surface of the ridge 135. In addition, the second electrode 160 is provided, for example, on the entire lower surface of the substrate 100.

In the semiconductor laser element L1 of the first embodiment, the width of the ridge 135 is set as follows.

The second region 2 has the first core region 21 having the refractive index n₂₁ and the first cladding regions 22 having the refractive index n₂₂ respectively provided on opposite sides of the first core region 21, and the width of the second ridge 135b is set so as to allow the laser beam to propagate in a plurality of desired transverse modes. In addition, the first electrode 150 is preferably provided so as to be in contact with the upper surface of the second ridge 135b without being in contact with the upper surfaces of the p-side cladding layers 132 on opposite sides outside the second ridge 135b.

The width of the first ridge 135a is set such that the equivalent refractive indexes of the plurality of transverse modes of the laser beam incident on the first region 1 from the second region 2 are substantially the same. Specifically, in consideration of the spread of the beam of the laser beam incident on the first region 1 from the second region 2, the width of the first ridge 135a is set so that the amount of leakage of light from opposite ends of the first region 1 does not differ due to the difference in the transverse mode. In addition, the first electrode 150 is preferably provided so as to be in contact with the upper surface of the first ridge 135a without being in contact with the upper surfaces of the p-side cladding layers 132 on opposite sides outward of the first ridge 135a.

The semiconductor laser element L1 of the first embodiment is configured in consideration of the maximum diffusion angle θₘₐₓ₁ of the laser beam emitted from the second region 2 and incident on the first region 1 as an index for preventing the amount of light leaked from opposite ends of the first region 1 from being substantially different. Specifically, in a cross section perpendicular to an optical axis of the laser beam, the width W1 of the first region 1 is set such that opposite end portions of the first region 1 in a direction perpendicular to a stacking direction of the semiconductor layered portion are located outside the virtual lines v1 each extending at the maximum diffusion angle θₘₐₓ₁ from corresponding one of opposite ends of an emission end face of the first core region 21 on the first region 1 side. The first region 1 in the present specification refers to a region having an equivalent refractive index n₁. The first region 1 includes a diffraction grating. The first region 1 preferably refers to a region including the first ridge 135a and the semiconductor layer immediately below the first ridge 135a. The emission end face of the first core region 1 indicates a boundary plane between the first region 1 and the first core region 21.

The first diffraction grating 105 is provided in the first region 1 whose width is set so that the light leakage amounts do not substantially differ due to the difference in the transverse modes. The first diffraction grating 105 is provided, for example, such that opposite ends of the first diffraction grating 105 extend to opposite ends of the first region 1.

In the semiconductor laser element L1 of the first embodiment according to the present disclosure configured as described above, the width of the waveguide in the second region 2 is set so as to enable laser oscillation including a plurality of desired transverse modes, and the width W1 of the first region 1 is set to be wide so as to be positioned outside the virtual lines v1 each extending from corresponding one of opposite ends of the emission end face of the first core region 21 at the maximum diffusion angle θₘₐₓ₁.

As a result, according to the semiconductor laser of the first embodiment, it is possible to provide the transverse multimode semiconductor laser element L1 capable of oscillating and allowing a laser beam to propagate in a plurality of transverse modes and having a small variation in oscillation wavelength for each transverse mode.

The reason why such an effect can be obtained by the semiconductor laser element L1 of the first embodiment will be described including the background of the semiconductor laser element L1 of the first embodiment.

The semiconductor laser element L1 of the first embodiment has a grating structure including a waveguide structure (including a waveguide) and a diffraction grating in a semiconductor layered portion. The semiconductor laser element L1 is, for example, a distributed feedback (DFB) laser diode or a distributed Bragg reflection (DBR) laser diode. The semiconductor laser element L1 including the waveguide and the diffraction grating in the semiconductor layered portion can oscillate the laser beam including a plurality of transverse modes by widening the width of the waveguide, and can achieve high output.

However, when laser oscillation is performed so as to include a plurality of transverse modes, there is a problem that the oscillation wavelength varies for each mode, and the oscillation wavelength varies. As a result of intensive studies to find the cause of this, the present inventor has obtained knowledge that when the width of the waveguide is increased, oscillation can be performed in a plurality of transverse modes, but on the other hand, the equivalent refractive index is different for each of the transverse modes because the amount of light leaking from the waveguide is different for each of the transverse modes. Then, in the portion provided with the diffraction grating, it has been found that the effective period of the diffraction grating is shifted due to the difference in the equivalent refractive index for each transverse mode, that is, the Bragg wavelength is shifted, and the oscillation wavelength varies. Therefore, in the semiconductor laser element L1 according to the first embodiment of the present disclosure, the width of the first region is widened so that the period of the diffraction grating does not shift for each transverse mode. In other words, in the semiconductor laser element L1 according to the first embodiment of the present disclosure, the width of the first region is increased to such an extent that the leakage amount of light from the first region does not become a problem for each transverse mode. As a result, it is possible to reduce the shift of the period of the diffraction grating for each transverse mode and reduce the variation in the oscillation wavelength due to the difference in the transverse mode.

Hereinafter, each configuration of the semiconductor laser element L1 according to the first embodiment will be described in detail with specific examples.

Note that the semiconductor laser element L1 according to the first embodiment is not limited to the following specific example as long as it has a basic configuration capable of obtaining the above effect.

### (Substrate 100)

The substrate 100 of the semiconductor laser element L1 of the first embodiment is, for example, a semiconductor substrate. The substrate 100 is, for example, a nitride semiconductor substrate such as a GaN substrate. The nitride semiconductor substrate may contain n-type impurities. The element to be the n-type impurity may be, for example, O, Si, or Ge. The upper surface of the substrate 100 can be a +c surface (that is, (0001) plane) using a nitride semiconductor substrate. In the first embodiment, the c surface is not limited to a plane strictly coinciding with the (0001) plane, and includes a plane having an off angle of ±1 degree or less, preferably ±0.03 degrees or less. The semiconductor laser element L1 do not have to have the substrate 2. As the upper surface of the substrate, an m plane, an a plane, an r plane, or the like may be used.

### (Semiconductor Layered Portion 101)

As described above, the semiconductor layered portion 101 may include; for example, the n-side semiconductor layer 110 including the n-side cladding layer 111 and the n-side light guide layer 112; the active layer 120 provided on the n-side semiconductor layer 110; and the p-side semiconductor layer 130 provided on the active layer 120 and including the p-side light guide layer 131 and the p-side cladding layer 132.

The semiconductor layer of the semiconductor layered portion 101 is, for example, a III-V semiconductor layer. Examples of the III-V semiconductor layer include a nitride semiconductor layer formed with a composition of In_{α}Al_{β}Ga_{1-α-β}N, (0≤α, 0≤β, α+β≤1).

Examples of the element to be the n-type impurity used for the nitride semiconductor layer include Si and Ge. Examples of the element to be the p-type impurity include Mg. Thus, each conductivity-type nitride semiconductor layer can be formed.

(n-Side Semiconductor Layer 110)

The n-side semiconductor layer 110 includes one or more semiconductor layers containing n-type impurities. The n-side semiconductor layer 110 may include, for example, an n-side cladding layer 111 having a refractive index n₁₁₁ and an n-side light guide layer 112 having a refractive index n₁₁₂. The n-side semiconductor layer 110 may further include an undoped layer not intentionally doped with impurities.

The refractive index n₁₁₁ and the refractive index n₁₁₂ are smaller than the refractive index n₁₂₀ of the active layer 120. The refractive index n₁₁₁ and the refractive index n₁₁₂ are different from each other, and for example, the refractive index n₁₁₁ is smaller than the refractive index n₁₁₂.

The n-side cladding layer 111 is disposed between the active layer 120 and the substrate 100. The n-side cladding layer 111 may be, for example, a nitride semiconductor layer. Examples of the nitride semiconductor include AlGaN and GaN. The film thickness of the n-side cladding layer 111 may be 0.45 μm or more and 3.0 μm or less. The content of the n-type impurity may be 1×10¹⁷ cm⁻³ or more and 5×10¹⁸ cm⁻³ or less.

The n-side light guide layer 112 is disposed between the active layer 120 and the n-side cladding layer 111. The n-side light guide layer 112 may be, for example, a nitride semiconductor layer. Examples of the nitride semiconductor include AlGaN, GaN, and InGaN. The film thickness of the n-side light guide layer 112 may be, for example, 0.05 μm or more and 0.5 μm or less. The content of the n-type impurity may be 1×10¹⁷ cm⁻³ or more and 5×10¹⁸ cm⁻³ or less.

### (Active Layer)

The active layer 120 is formed on the n-side light guide layer 112. The active layer 120 emits, for example, light having a wavelength of 360 nm or more and 520 nm or less. The active layer 120 may have a quantum well structure including one or more well layers and a plurality of barrier layers. The well layer and the barrier layer are, for example, GaN, InGaN, AlGaN, or AlInGaN. The well layer is, for example, AlGaN, GaN, or InGaN, and is a nitride semiconductor having band gap energy lower than that of the barrier layer. The active layer 120 may be a multiple quantum well structure or a single quantum well structure. Any one or both of the well layer and the barrier layer may contain impurities.

(p-Side Semiconductor Layer 130)

The p-side semiconductor layer 130 includes one or more semiconductor layers containing p-type impurities. The p-side semiconductor layer 130 is formed on the active layer 120. The p-side semiconductor layer 130 may include, for example, a p-side light guide layer 131 having a refractive index n₁₃₁ and a p-side cladding layer 132 having a refractive index n₁₃₂ in this order from the substrate 100 side (that is, from the active layer 120 side). The p-side semiconductor layer 130 may include other layers. The p-side semiconductor layer 130 may have an undoped layer that is intentionally not doped with impurities.

The refractive index n₁₃₁ and the refractive index n₁₃₂ are smaller than the refractive index n₁₂₀ of the active layer 120. The refractive index n₁₃₁ and the refractive index n₁₃₂ are different from each other. For example, the refractive index n₁₃₁ is larger than the refractive index n₁₃₂.

The p-side light guide layer 131 may be, for example, a nitride semiconductor layer. Examples of the nitride semiconductor include AlGaN and GaN. The film thickness of the p-side light guide layer 131 may be 0.05 μm or more and 0.25 μm or less. The p-side light guide layer 131 may be an undoped layer, and may contain p-type impurities in a range of 1×10¹⁶ cm⁻³ or more and 1×10¹⁸ cm⁻³ or less.

The p-side cladding layer 132 may be, for example, a nitride semiconductor layer. Examples of the nitride semiconductor include AlGaN and GaN. It may have a single-layer structure or a multilayer structure in which nitride semiconductor layers having different compositions are stacked. The content of the p-type impurity may be 1×10¹⁷ cm⁻³ or more and 1×10²⁰ cm⁻³ or less. The p-side cladding layer 132 may include a p-side contact layer. The p-side contact layer may be, for example, a nitride semiconductor.

### (Ridge)

As illustrated in FIGS. 2, 4, 5, and the like, a ridge 135 is provided on the upper surface of the p-side semiconductor layer 130 of the semiconductor layered portion 101. FIG. 3A is a cross section taken along line III-III in FIG. 2, FIG. 4 is a cross section taken along line IV-IV in FIG. 2, and FIG. 5 is a cross section taken along line V-V in FIG. 2. The ridge 135 is provided, for example, on a part of the upper surface of the p-side cladding layer 132. The ridge 135 includes a first ridge 135a and a second ridge 135b. The first ridge 135a is provided in the first region 1. The second ridge 135b is provided in the second region 2, and the width of the second ridge 135b is narrower than the width of the first ridge 135a. The first ridge 135a is provided continuously with the second ridge 135b so that, for example, the center axis in the waveguide direction coincides with the optical axis of the second region 2.

The first electrode 150 is provided so as to be in contact with the upper surface of the first ridge 135a and the upper surface of the second ridge 135b. The first electrode 150 may be provided by separating an electrode portion connected to the upper surface of the first ridge 135a and an electrode portion connected to the upper surface of the second ridge 135b.

The waveguide structure body of the first region 1 is formed below the first ridge 135a on which upper surface, the first electrode 150 is provided. As described above, the waveguide structure body of the first region 1 is configured such that there is substantially no leakage of light from opposite end portions, and the spread of light in the transverse direction is not limited. In other words, the first region 1 in the first embodiment is a region including the first ridge 135a and the semiconductor layer (p-side semiconductor layer 130, active layer 120, n-side semiconductor layer 110) immediately below the first ridge 135a, and the lateral ends of the first ridge 135a may be located inside opposite lateral faces of the semiconductor layered portion 101. In addition, the ridge 135 may be only the second ridge 135b without providing the first ridge 135a. In this case, opposite lateral faces of the semiconductor layered portion 101 coincide with opposite ends of the first region 1. The end of the first region 1 refers to the end of the first region 1 in the transverse direction, that is, in a direction orthogonal to the periodic direction of the first diffraction grating 105 and the stacking direction of the semiconductor layered portion 101. As described above, the width of the first region 1 is set such that the equivalent refractive indexes of the plurality of transverse modes of the laser beam incident on the first region 1 from the second region 2 are substantially the same.

The second ridge 135b is provided at a center portion of the upper surface of the p-side semiconductor layer 130 in the second region 2 at a predetermined interval from opposite lateral faces of the second region 2. As a result, in the second region 2, the first core region having the refractive index n₂₁ below the second ridge 135b and the first cladding regions having the refractive index n₂₂ respectively on opposite sides outside the first core region are formed, and the waveguide structure of the second region 2 is formed. In the semiconductor laser element L1 according to the first embodiment, the width of the first core region, that is, the width of the second ridge 135b is set such that the laser beam including a plurality of desired transverse modes propagate.

As illustrated in FIGS. 4 and 5, the cross-sectional shape of the ridge 135 is, for example, a trapezoidal shape in which the width decreases as the distance from the substrate 100 increases, but is not limited to this trapezoidal shape, and may be an inverted trapezoidal shape in which the width increases as the distance from the substrate 100 increases, or may be a rectangle in which the width is constant. In FIG. 2, a broken line indicates that the ridge 135 has a trapezoidal shape. Further, the ridge 135 may be an buried ridge as long as a waveguide structure described later can be realized, and is not limited to a ridge semiconductor laser as long as a waveguide structure described later can be realized. In the present specification, the width of the ridge refers to the width of the widest portion of the ridge in the transverse direction.

### (Waveguide Structure)

Hereinafter, the waveguide structure of the semiconductor laser element L1 according to the first embodiment will be described in detail.

First, the waveguide structure of the second region 2 will be described, and next, the waveguide structure of the first region 1 will be described.

The waveguide structure of the second region 2 includes a first core region 21 having a refractive index n₂₁ and first cladding regions 22 respectively positioned on opposite sides outside the first core region 21 and having a refractive index n₂₂, and is a waveguide that allows light to propagate in the longitudinal direction of the first core region 21 in a plurality of transverse modes (that is, transverse multimode). The number of transverse modes is determined by the width of the first core region 21 and the difference between the refractive index n₂₁ of the first core region 21 and the refractive index n₂₂ of the first cladding regions 22 respectively located on opposite sides outside the first core region 21. The width of the first core region 21 is a width defined in a direction perpendicular to the stacking direction of the semiconductor layered portion in a plane perpendicular to the optical axis of the waveguide. In addition, the thickness of the first core region 21 is a thickness in the stacking direction of the semiconductor layered portion in a plane perpendicular to the optical axis of the waveguide. In the first embodiment, the first core region 21 includes the second ridge 135b, and the first core region 21 is a region which is defined by the width of the second ridge 135b. The first core region 21 includes at least the n-side semiconductor layer 110, active layer 120, and p-side semiconductor layer 130. The first cladding regions 22 are the regions which sandwich the first core region 21. The first cladding region 22 includes at least the n-side semiconductor layer 110, active layer 120, and p-side semiconductor layer 130. The refractive index n₂₁ of the first core region 21 and the refractive index n₂₂ of the first cladding region 22 are each an equivalent refractive index being focused on the height direction of each region.

To illustrate with a simple configuration, a symmetric three-layer flat waveguide is assumed. The number N of transverse modes of light propagating through the first core region 21 can be set on the basis of the following Formula 1 by obtaining the normalized frequency V defined by the refractive index n₂₁ of the first core region 21, the refractive index n₂₂ of the first cladding region 22, and the width of the first core region 21.

$$V \geq N π / 2 \qquad ( Formula 1 )$$

(N is an integer of 1 or more)

The normalized frequency V is expressed as follows.

$$V = {k}_{0} {n}_{21} a {( 2 Δ )}^{1 / 2}$$

“k₀” is a wave number in vacuum, “a” is a half width of the first core region 21, and Δ(=(n₂₁²−n₂₂²)/(2n₂₁²)) is a relative refractive index difference.

In Formula 1, N is the mode order of the transverse mode, and for example, when the normalized frequency V is π/2 or more and less than 2π/2 (that is, π), light can propagate in two modes of a zeroth-order mode (fundamental mode) and a first-order mode. When the normalized frequency V is Nπ/2 or more and less than (N+1) π/2, light can propagate in zeroth-order, first-order, and second-order, . . . . Nth-order modes, that is, a plurality of modes of (N+1).

In this manner, the number of transverse modes of light propagating through the second region 2 can be set on the basis of Formula 1. Specifically, the number of transverse modes can be set on the basis of the width of the second ridge 135b. Also in a semiconductor laser element not having a ridge structure, the number of transverse modes can be similarly set on the basis of parameters constituting the waveguide.

The number of the transverse modes is preferably as large as possible for higher output, and is, for example, 10 or more, preferably 30 or more, and more preferably 50 or more. The number of the transverse modes is preferably as large as possible for higher output, but if the number is too large, there is an disadvantage such as deterioration of the light condensing property, and thus for example, the number is 500 or less, preferably 300 or less, and more preferably 100 or less.

As can be understood from the above description of Formula 1, the number of transverse modes is determined by parameters including the width of the first core region 21. In consideration of the number of transverse modes and heat dissipation, the width of the first core region 21 is, for example, 15 μm or more and 100 μm or less, and more preferably 45 μm or more and 90 nm or less.

### (First Diffraction Grating 105)

As illustrated in FIG. 1 and the like, the first diffraction grating 105 is provided in the first region 1. In the semiconductor laser element L1 according to the first embodiment, the first region 1 is a region having a small difference in equivalent refractive index with respect to the transverse modes of different orders, and the variation in equivalent refractive index is small, so that the variation in wavelength selection by the diffraction grating can be reduced. This is because the shift of the effective period of the diffraction grating for each transverse mode is reduced. As a result, it is possible to reduce the variation in the oscillation wavelength due to including the plurality of transverse modes. In the semiconductor laser element L1 according to the first embodiment, the first region 1 is a region having substantially the same equivalent refractive index with respect to transverse modes of different orders. As a result, the oscillation wavelengths can be made substantially the same. The Bragg wavelength in the diffraction grating is expressed by the following Formula 2. Formula 2 indicates that the effective period of the diffraction grating is a product of the equivalent refractive index and the pitch of the diffraction grating. When the equivalent refractive index (n_{eq}) varies depending on the order of the transverse mode, the wavelength reflected by the diffraction grating varies depending on the order of the transverse mode. As a result, when the order of the transverse mode is different, the oscillation wavelength is different. However, in the first embodiment, because the variation in the equivalent refractive index (n_{eq}) of the first region 1 is reduced, the variation in the oscillation wavelength can be reduced. That is, the width of the first region 1 is larger than the spread of the laser beam. As a result, the variation in the equivalent refractive index (n_{eq}) due to the difference in the order of the transverse mode of the first region 1 is reduced. Therefore, the variation in the oscillation wavelength caused by the order of the transverse mode can be reduced. In this embodiment, the equivalent refractive index (n_{eq}) is the refractive index n₁. Therefore, n₁ can be calculated from the Bragg wavelength and the pitch of the diffraction grating.

$$Bragg wavelength ( {λ}_{B} ) = ( equivalent refractive index ( {n}_{eq} ) \times pitch of diffraction grating ( P ) ) \times 2 \qquad ( Formula 2 )$$

The interval between opposite ends of the first diffraction grating 105 is, for example, 1.5 times or more and 100 times or less, and more preferably 3 times or more and 10 times or less the width of the first core region.

That is, when the width of the first core region 21 is, for example, 15 μm or more and 100 μm or less, the interval between the ends of the first diffraction grating 105 is 22.5 μm or more and 10,000 μm or less, more preferably 45 μm or more and 1000 μm or less, and still more preferably 45 μm or more and 500 μm or less.

In addition, the interval between opposite ends of the first diffraction grating 105 may be constant, and the interval between opposite ends may be increased from the second region side toward the laser beam emission end face side of the first region.

The diffraction grating can be formed by alternately (periodically) providing regions having different refractive indexes in a light propagation direction. The diffraction grating is provided, for example, between two adjacent semiconductor layers. The pitch of the diffraction grating can be appropriately selected in consideration of the wavelength of light emitted from the active layer 120. The pitch of the diffraction grating may be, for example, 60 nm or more and 400 nm or less, and preferably 70 nm or more and 300 nm or less.

In the first embodiment, for example, as illustrated in FIG. 3A, the first diffraction grating 105 is provided between the n-side light guide layer 112 and the n-side cladding layer 111. Specifically, the first diffraction grating 105 alternately includes one or more first protrusions 61 provided on the surface of the n-side cladding layer 111 and one or more second protrusions 62 provided on the surface of the n-side light guide layer 112 in the traveling direction of light.

In the first embodiment, the first diffraction grating 105 is provided between the n-side light guide layer 112 and the n-side cladding layer 111, but may be provided only in either the n-side light guide layer 112 or the n-side cladding layer 111, or may be provided between the n-side light guide layer 112 and the active layer 120. In addition, the first diffraction grating 105 may be provided on the p-side semiconductor layer 130 side as illustrated in FIG. 3B. FIG. 3B is a schematic cross-sectional view of another mode of the semiconductor laser element L1 illustrated in FIG. 2, taken along line III-III.

### (Electrode)

As illustrated in FIGS. 3A to 5, the semiconductor laser element L1 includes a first electrode 150 and a second electrode 160. The first electrode 150 is a positive electrode, and the second electrode 160 is a negative electrode.

For example, when the substrate 100 has conductivity, the second electrode 160 can be disposed on the lower surface of the substrate 100. When the substrate 100 has an insulating property, a part of the n-side cladding layer 111 can be exposed and formed on the exposed surface.

Examples of the material of the first electrode 150 and the second electrode 160 include a single-layer film or a multilayer film of a metal or an alloy of Ni, Rh, Cr, Au, W, Pt, Ti, Al, or the like, a conductive oxide containing at least one selected from Zn, In, and Sn, or the like.

The first electrode 150 may include a light-transmissive conductive film in contact with the ridge 135. By selecting a material having a smaller refractive index of the light-transmissive conductive film than the refractive index of the active layer 120 or the refractive index of the p-side semiconductor layer 130, the light-transmissive conductive film can be treated as a cladding layer on the p-side. The light-transmissive conductive film is, for example, indium tin oxide (ITO) or indium gallium zinc oxide (IGZO). The cladding layer on the p-side may further include an insulating layer 140 disposed to narrow the current path. The insulating layer 140 may be, for example, silicon oxide, aluminum oxide, aluminum nitride, or the like.

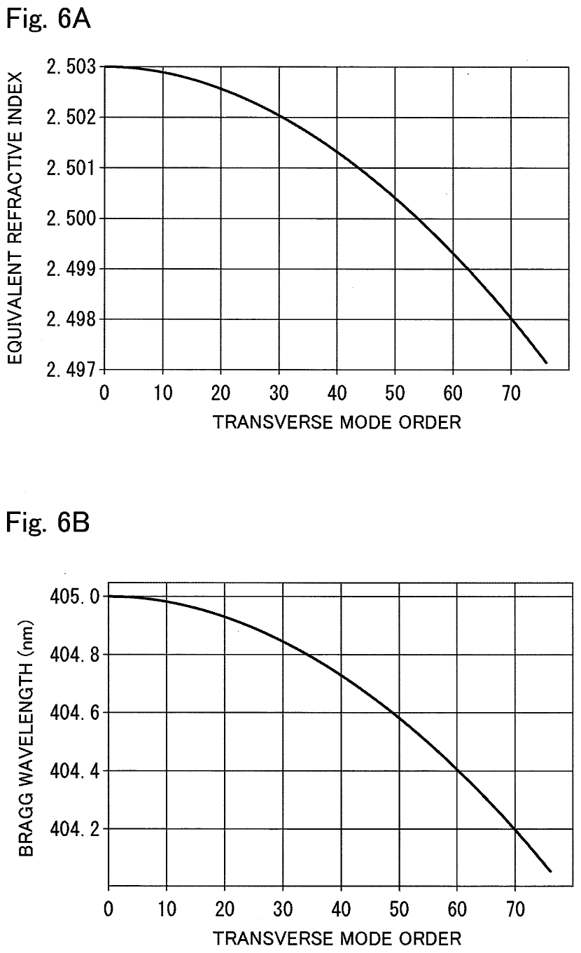

An oscillation wavelength when it is assumed that a diffraction grating is formed in a symmetric three-layer flat waveguide will be described by way of simulation. FIG. 6A is a graph illustrating a relationship between a transverse mode order and an equivalent refractive index. FIG. 6B is a graph illustrating a relationship between a transverse mode order and a Bragg wavelength. As simulation conditions, the refractive index of the core was 2.503, the refractive index of the cladding was 2.497, the pitch of the diffraction grating was about 80.9 nm, and the core width of the waveguide was 90 μm. Under this condition, it was suggested that a higher order mode having a mode order that is 70 or more can be obtained. In FIG. 6A, when the zeroth-order mode was compared with, for example, the 70th-order mode, the difference in equivalent refractive index was 0.005. This result was converted into the Bragg wavelength using the above-described Formula 2 as shown in FIG. 6B. As in FIG. 6A, when the zeroth-order mode was compared with the 70-th order mode, the difference in Bragg wavelength was about 0.8 nm. This result was due to a difference occurring in the equivalent refractive index caused by a difference in the light leakage amount into the cladding layer for each mode. As described above, it was suggested that in a case of the transverse multimode waveguide, that is, in a case where the diffraction grating is provided in a state where a plurality of transverse modes are confined in the transverse direction, the variation in the oscillation wavelength is large.

On the other hand, in the semiconductor laser element L1 of the first embodiment, the width of the first region is larger than the width of the waveguide of the second region. Therefore, in the semiconductor laser element L1 of the first embodiment, the laser beam incident from the second region 2 to the first region 1 propagates while spreading in the transverse direction in the first region, but the width of the first region is larger than the width of the spread laser beam. Therefore, the first region cannot be regarded as an optical confinement structure with respect to the transverse direction for light, and each transverse mode of the laser beam senses the refractive index n₁ of the first region. Thus, from Formula 2, the Bragg wavelengths are the same. Depending on the size of the width of the first region 1, the laser beam can slightly spread out of the first region 1. However, in the case of a slight spread, because most of the transverse modes sense the refractive index n₁, the difference in the equivalent refractive index decreases, and the difference in the Bragg wavelength based on Formula 2 decreases.

(Setting of Maximum Diffusion Angle θₘₐₓ₁)

In the semiconductor laser element L1 according to the first embodiment, the maximum diffusion angle θₘₐₓ₁ can be obtained using an M² factor that is an index indicating the quality of the laser beam given by the following Formula 3. The M² factor is an index indicating the spread from the ideal Gaussian beam, and the M² factor is 1 in the ideal Gaussian beam. That is, if the M² factor of the laser beam output from the semiconductor laser element L1 is known, it is possible to know how much the laser beam spreads as compared with the ideal Gaussian beam, and to obtain the maximum diffusion angle θₘₐₓ₁.

$${M}^{2} = πφ {W}_{0} / λ \qquad ( Formula 3 )$$

W₀ is a beam waist radius, and φ is a beam divergence angle.

In addition, λ is a wavelength of the laser beam in vacuum.

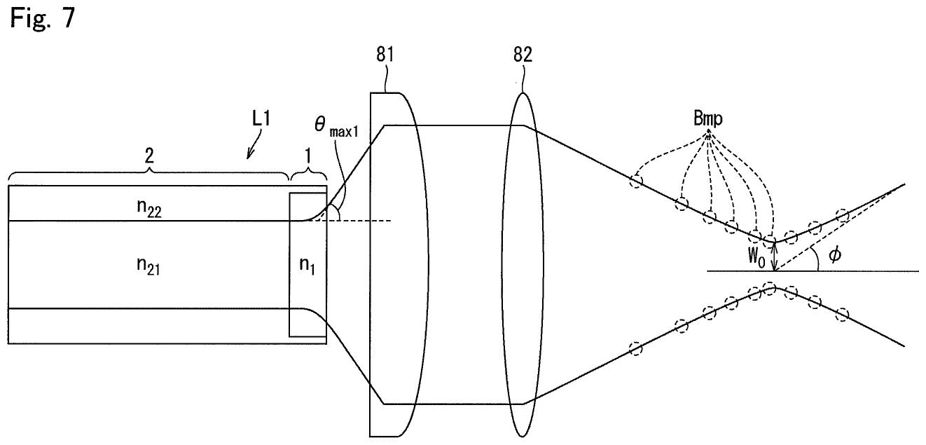

The beam waist radius W₀ and the beam divergence angle φ can be measured as follows using an optical system including the collimator lens 81 and the condenser lens 82 illustrated in FIG. 7.

The laser beam emitted from the first region 1 is collimated by the collimator lens 81, and the laser beam is condensed by the condenser lens 82 to follow the trajectory of the condensed laser beam. Specifically, the beam diameter of the condensed laser beam is measured at various positions Bmps, a position where the beam diameter becomes the smallest is estimated, and the beam diameter (beam waist radius W₀) at the position is obtained. The beam divergence angle φ is obtained by measuring the spread of the beam from the position where the beam diameter is minimized. The definition of the parameters required to determine the M² factor is based on the international standard ISO 11146-1:2021 or ISO 11146-2:2021. For example, the beam diameter is defined by D4σ (second moment width). The current value input to the semiconductor laser element L1 when the M² factor is measured is within a predetermined drive current (operating current) range.

The M² factor is calculated from Formula 3 using the beam waist radius W₀ and the beam divergence angle φ obtained as described above, and the maximum diffusion angle θₘₐₓ₁ is obtained based on the M² factor as described above. The trajectory of the laser beam emitted from the second region can be seen from the M² factor and the trajectory of the laser beam measured in the process of obtaining the M² factor. As a result, the virtual line v1 spreading from opposite ends of the emission end face of the first core region at the maximum diffusion angle θₘₐₓ₁ is obtained. The spread of the laser beam in the first region 1 can be examined by comparing the positional relationship between the virtual line and opposite ends of the first region 1.

As illustrated in FIG. 7 and the like, the maximum diffusion angle θₘₐₓ₁ is an angle formed by a straight line excluding a curved portion in the virtual line and a straight line extending a boundary between the first core region 21 and the first cladding region 22.

In addition, the M² factor of the laser beam in the first embodiment may be two or more and 100 or less.

When the beam diameter of the laser beam on the laser beam emission end face is smaller than the width of the first region 1 and the width of the first region 1 is substantially constant, it is obvious that opposite ends of the first region 1 are located outside the virtual lines v1. Therefore, first, the positional relationship between the width of the first region 1 and the virtual line v1 can be found by measuring the beam diameter of the laser beam at the laser beam emission end face.

As understood from the above description, the maximum diffusion angle θₘₐₓ₁ is an index indicating the maximum spread of the laser beam emitted from the second region 2. The leakage of the laser beam to the further outside of the maximum spread is a leakage amount to such an extent that the equivalent refractive index is not substantially affected, in other words, a leakage amount of light to such an extent that the equivalent refractive indexes are substantially the same for all the transverse modes regardless of the mode order. Therefore, on the basis of the maximum diffusion angle θₘₐₓ₁, which is an index indicating the maximum spread of the laser beam emitted from the second region 2, the semiconductor laser element L1 according to the first embodiment in which the first diffraction grating 105 is provided in the first region 1 in which opposite ends are formed outside the maximum spread of the laser beam can reduce the variation in the oscillation wavelength due to the difference in the transverse mode.

### (Laser Oscillation)

The semiconductor laser element L1 according to the first embodiment having the above configuration can cause laser oscillation by applying a voltage to the first electrode 150 and the second electrode 160 and supplying a current into the active layer 120.

As illustrated in FIG. 2 and the like, the semiconductor laser element L1 according to the first embodiment includes an antireflection coating (AR coating) 210 provided on an end face of the first region 1 that is opposite to the second region 2 and a high reflection coating (HR coating) 220 provided on an end face of the second region 2 that is opposite to the first region 1, and the laser beam is emitted via the AR coating 210. The reflectance of the AR coating 210 at the wavelength of the laser beam may be 0.01% or more and 1% or less. The reflectance of the HR coating 220 at the wavelength of the laser beam may be 99% or more and 99.99% or less.

As described above, in the first embodiment, because the equivalent refractive indexes of the laser beam incident from the second region 2 to the first region 1 in the plurality of transverse modes are set to be substantially the same, it is possible to reduce the variation in the oscillation wavelength due to the difference in the transverse mode. Therefore, the full width at half maximum of the spectral linewidth of the laser beam emitted through the AR coating 210 can be reduced. The full width at half maximum of the spectral linewidth of the laser beam emitted from the semiconductor laser element L1 is, for example, 0.01 nm or more and 0.6 nm or less. The upper limit value of the full width at half maximum of the spectral linewidth of the laser beam is preferably 0.5 nm or less, more preferably 0.3 nm or less, and still more preferably 0.1 nm or less.

In the first embodiment, the semiconductor laser element L1 of the first embodiment has been described by taking the semiconductor laser element having the ridge structure as an example.

However, the semiconductor laser element L1 of the first embodiment is not limited to a semiconductor laser element having a ridge structure, and may be a rib waveguide-type semiconductor laser element or a buried heterostructure waveguide-type semiconductor laser element.

That is, the transverse multimode semiconductor laser element L1 according to the first embodiment is not particularly limited as long as the transverse multimode semiconductor laser element includes a semiconductor layered portion including an active layer and having a waveguide structure.

The semiconductor layered portion includes
(i) a first region that includes a first diffraction grating and has a refractive index n₁, and
(ii) a second region that includes a first core region having a refractive index n₂₁ and first cladding regions having a refractive index n₂₂ respectively provided on opposite sides of the first core region, and allows a laser beam to propagate in a plurality of transverse modes;
(iii) the laser beam emitted from the second region propagates through the first region at a maximum diffusion angle θₘₐₓ₁ determined by the refractive index n₁, the refractive index n₂₁, and the refractive index n₂₂; and
in a cross section perpendicular to an optical axis of the laser beam, opposite end portions of the first region in a direction perpendicular to a stacking direction of the semiconductor layered portion are located outside the virtual lines each extending at the maximum diffusion angle θₘₐₓ₁ from corresponding one of opposite ends of an emission end face of the first core region on the first region side.

Hereinafter, a mode in which the semiconductor laser element L1 of the first embodiment focusing on the maximum diffusion angle θₘₐₓ₁ is defined without using the maximum diffusion angle θₘₐₓ₁ will be described.

### First Form

For example, the semiconductor laser element L1 of the first embodiment can also be specified using a ridge structure and a full width at half maximum of the spectral linewidth of a laser beam emitted from the semiconductor laser element, instead of the maximum diffusion angle θₘₐₓ₁. When the semiconductor laser element L1 has a first region having the first diffraction grating and a second region that is a transverse multimode waveguide and is narrower than the first region, the wavelength of the output laser beam is selected by the above-described Formula 2. In Formula 2, when the equivalent refractive indexes of the transverse modes are the same or close to each other, the full width at half maximum of the spectral linewidth of the laser beam is narrowed. This is because the oscillation wavelengths of the respective transverse modes are the same or close to each other. In other words, when the semiconductor laser element has the first region having the first diffraction grating and the second region which is narrower than the first region and is the transverse multimode waveguide, if the full width at half maximum of the oscillation wavelength is narrower, it can be said that the equivalent refractive indexes of the respective transverse modes are the same or close in Formula 2. For example, when the waveguide structure of the first region is the same as the waveguide structure of the second region, the full width at half maximum of the spectral linewidth of the laser beam can be larger than 0.6 nm. However, in the semiconductor laser element defined by focusing on the maximum diffusion angle θₘₐₓ₁, the oscillation wavelength can be made substantially the same for each transverse mode, and the full width at half maximum of the spectral linewidth of the laser beam can be narrowed to 0.6 nm or less. As a result, the intensity of the laser beam at the peak wavelength can also be increased. As a result of further detailed examination, the configuration of the first ridge 135a and the second ridge 135b and the relationship therebetween are defined, and the full width at half maximum of the spectral linewidth of the laser beam emitted from the semiconductor laser element is specified to be 0.6 nm or less, so that the semiconductor laser element of the first embodiment is defined from another viewpoint without including the maximum diffusion angle θₘₐₓ₁.

Specifically, the semiconductor laser element according to the first form includes:
a semiconductor layered portion including an active layer,
the semiconductor layered portion including
(i) a first region including a first diffraction grating and
(ii) a second region having a transverse multimode waveguide;
the first region having a first ridge;
the second region having a second ridge; and
in a cross-sectional view orthogonal to a periodic direction of the first diffraction grating,
(iii) a width of the first ridge is larger than a width of the second ridge in a direction orthogonal to the stacking direction of the semiconductor layered portion, and
(iv) a full width at half maximum of a spectral linewidth of a laser beam emitted from the semiconductor laser element is 0.01 nm or more and 0.6 nm or less.

As a result, it is possible to provide a transverse multimode semiconductor laser element having a small variation in oscillation wavelength for each transverse mode. The full width at half maximum of the spectral linewidth of the laser beam output from the semiconductor laser element is preferably 0.5 nm or less, more preferably 0.3 nm or less, and still more preferably 0.1 nm or less. After being emitted from the second region 2, the laser beam travels straight in the first region 1 from the end face of the second region 2 to about the length of the Rayleigh length, and then diffuses at the maximum diffusion angle θₘₐₓ₁. For example, the laser beam emitted from the second region 2 can behave as a solid line shown in FIG. 7. The spread of the beam reflecting the behavior of the laser beam is inside the virtual line v1 in FIG. 1. Therefore, even if opposite ends of the first region 1 are inside the virtual lines v1, if opposite ends of the first region 1 are outside the spread of the beam reflecting the behavior of the laser beam as illustrated in FIG. 7, each transverse mode senses substantially the same equivalent refractive index in the first region 1. Therefore, the variation in the oscillation wavelength can be reduced from Formula 2. In addition, as a result of wavelength selection by the first diffraction grating 105, if the full width at half maximum of the spectral linewidth of the laser beam falls within the above range, a part of opposite ends of the first region 1 may be inside virtual lines based on the maximum diffusion angle θₘₐₓ₁. If the amount of light leaking from the first region 1 is small, the equivalent refractive index for the transverse mode is substantially the refractive index of the first region 1. Therefore, the variation in the oscillation wavelength can be reduced from Formula 2.

### Second Form

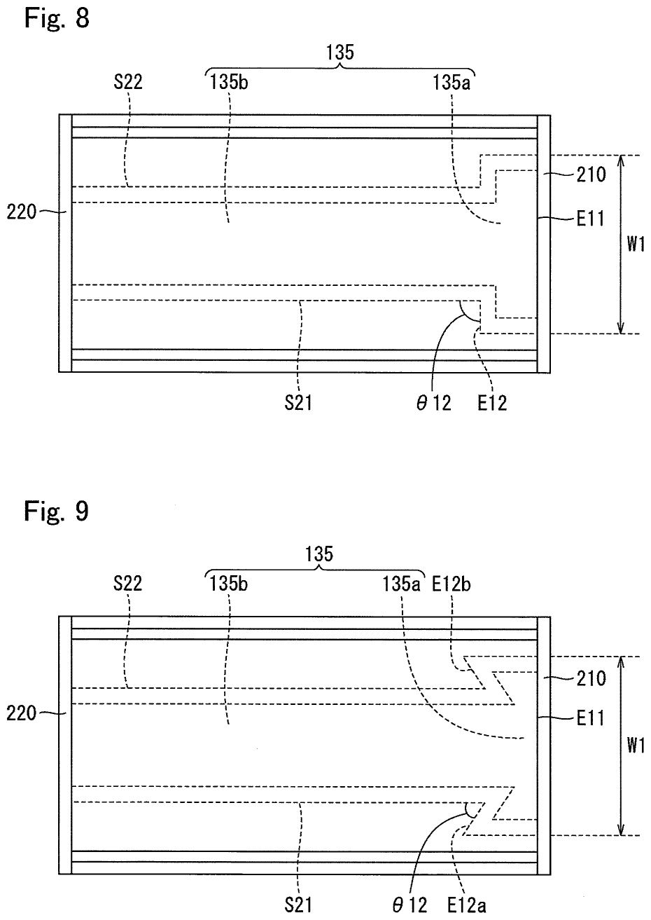

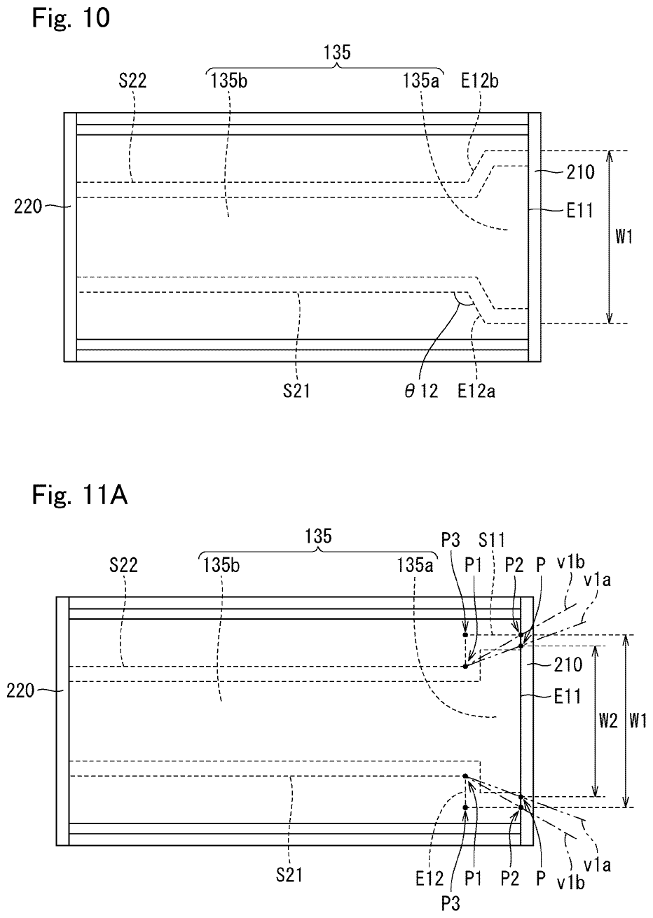

As illustrated in FIGS. 8 to 10, the semiconductor laser element L1 according to the first embodiment can be defined without using the maximum diffusion angle θₘₐₓ₁ by more specifically defining the structure of the ridge and the relationship between the regions.

Specifically, the semiconductor laser element according to the second form includes:
a semiconductor layered portion including an active layer,
the semiconductor layered portion including
(i) a first region including a first diffraction grating and
(ii) a second region having a transverse multimode waveguide;
the first region having a first ridge 135a having a first end face E11 on a side where the laser beam is emitted and second end faces E12a and E12b on a side opposite to the first end face E11;
the second region has a second ridge 135b having a first lateral face S21 and a second lateral face S22 opposite to the first lateral face S21; and
in a cross-sectional view orthogonal to a periodic direction of the first diffraction grating,
(iii) a width of the first end face E11 in a direction orthogonal to the stacking direction of the semiconductor layered portion is larger than a beam diameter of the laser beam, and
(iv) an angle formed by the second end face E12a and the first lateral face S21 and an angle formed by the second end face E12b and the second lateral face S22 are each 30° or more and 120° or less. The second end face E12a and the second end face E12b are also collectively referred to as a second end face E12.

Preferably (iv) the angle between the second end face E12a and the first lateral face S21 and the angle between the second end face E12b and the second lateral face S22 are 45° or more and 120° or less, more preferably 60° or more and 120° or less, still more preferably 80° or more and 120° or less, and most preferably 90° or more and 120° or less.

The width of the first end face E11 of the first ridge 135a is larger than the beam diameter of the laser beam on the first end face E11. In addition, by setting the angle formed by the second end face E12a of the first ridge 135a and the first lateral face S21 of the second ridge 135b and the angle formed by the second end face E12b of the first ridge 135a and the second lateral face S22 of the second ridge 135b to predetermined angles, the width of the first region 1 can be maintained in a state of being larger than the spread of the laser beam incident on the first region 1 from the second region 2. That is, the equivalent refractive indexes of the transverse modes in the first region 1 can be made substantially the same. As a result, it is possible to provide a transverse multimode semiconductor laser element having a small variation in oscillation wavelength for each transverse mode.

In top view, the shape of the first ridge 135a may be a trapezoid, a rectangle, a recessed shape, a racetrack shape, a bowl shape, a shape obtained by combining a rectangle and a trapezoid, or a shape obtained by combining a rectangle and a triangle. In top view, the two lateral faces of the first ridge 135a may be straight lines, curves expanding in a direction away from the second region, or arcs. The two lateral faces of the first ridge 135a are preferably straight, and the two lateral faces of the first ridge 135a are preferably parallel. Accordingly, because the width of the first region 1 can be increased, the equivalent refractive index of the first region 1 can be easily controlled.

### Third Form

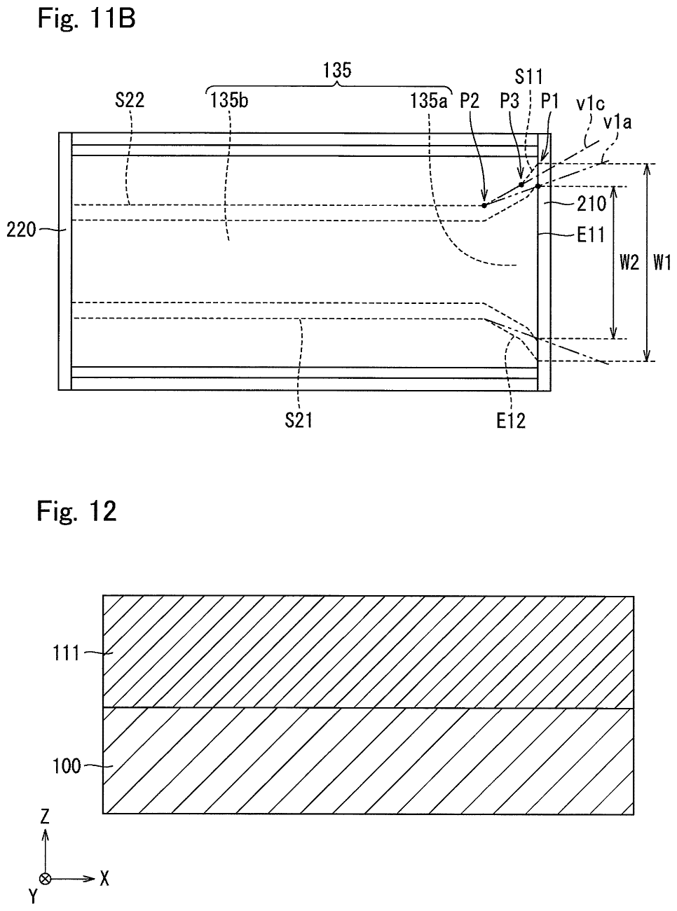

As illustrated in FIG. 11A, by more specifically defining the relationship between the width of the first end face E11 and the beam diameter at the emission end face, the semiconductor laser element L1 according to the first embodiment can also be defined without using the maximum diffusion angle θₘₐₓ₁.

Specifically, the semiconductor laser element according to the third form includes:
a semiconductor layered portion including an active layer.

The semiconductor layered portion includes
(i) a first region including a first diffraction grating, and
(ii) a second region that has a first core region and first cladding regions respectively provided on opposite sides of the first core region, and allows a laser beam to propagate in a plurality of transverse modes;
the first region has a first end face E11 that emits the laser beam;
in a cross-sectional view orthogonal to a periodic direction of the diffraction grating,
(iii) in a direction orthogonal to a stacking direction of the semiconductor layered portion, a width of the first end face E11 is larger than a beam diameter of the laser beam; and
in top view,
(iv) in a direction orthogonal to a periodic direction of the first diffraction grating, the first region also expands in a direction away from a center of the laser beam with respect to a shorter line v1a among lines connecting an end P of the beam and a first vertex P1 that is a boundary between the first region and a first core region of the second region.

As a result, the semiconductor laser element can emit a laser beam having a small variation in oscillation wavelength. In the transverse direction of the first region 1, the line v1a is outside the spread of the laser beam in consideration of the Rayleigh length. Therefore, if the width of the first region 1 on the emission end face E11 is larger than the beam diameter and the first region 1 spreads in a direction away from the center of the laser beam with reference to the line v1a, the first region 1 is also located outside the spread of the laser beam. As a result, the light propagating through the first region 1 senses substantially the same equivalent refractive index in any transverse mode. Therefore, the variation in the wavelength selected by the first diffraction grating 105 provided in the first region 1 is reduced. The end P of the beam on the first end face E11 is determined by the beam diameter. The beam diameter is determined on the basis of D4σ as illustrated in FIG. 7. In top view, that is in the FIG. 11A, the boundary between the first region 1 and the second region 2 can be shown by a straight line including two first vertices P1. As illustrated in FIG. 11A, each of two first vertices P1 is located on the line at which the boundary between the first core region 21 and the first cladding region 22 meets the boundary between the first region 1 and the second region 2.

The above-described (iv) may be, preferably, (iv-1) in the direction orthogonal to the periodic direction of the first diffraction grating, the first region 1 spreads in a direction away from the center of the laser beam with respect to a shorter line v1b of lines connecting the second vertex P2 of the first region 1 overlapping the first end face E11 and the first vertex P1 that is the boundary between the first region 1 and the first core region 21 of the second region 2. Because the line v1b spreads in a direction away from the center of the laser beam with respect to the line v1a, if the first region 1 spreads outside the line v1b, the first region 1 spreads with a margin with respect to the spread of the light, and the semiconductor laser element can more efficiently emit the laser beam having a small variation in oscillation wavelength.

In the above-described (iv-1), the line v1b connecting the first vertex P1 and the second vertex P2 may be a line connecting the second vertex P2 of the first ridge 135a overlapping the first ridge 135a and the first end face E11 and the first vertex P1 that is the boundary between the first ridge 135a and the second ridge 135b as illustrated in FIG. 11A in a case where the ridge 135 is formed. As illustrated in FIG. 11A, the first ridge 135a has a second end face E12 on the opposite side of the first end face E11. The first end face E11 and the second end face E12 are connected by a lateral face S11. Therefore, the intersection point P3 between the second end face E12 and the lateral face S11 is located in a direction away from the center of the laser beam with reference to the line v1b.

It can be said that the above-described (iv-1) specifies the positional relationship between the third vertex P3 and the line via connecting the first vertex P1 and the second vertex P2, but is not limited to the example of FIG. 11A. For example, as illustrated in FIG. 11B, the third vertex P3 may be located between the line via and the virtual line v1. In this case, in place of (iv-1) described above, (iv-2) it may be paraphrased that the first region also extends in a direction away from the center of the laser beam with reference to a line v1c connecting the third vertex P3 and the second vertex P2. Also in this case, because the light propagating through the first region 1 senses substantially the same equivalent refractive index in all the transverse modes, the variation in the wavelength selected by the first diffraction grating 105 becomes small. The shape of the first ridge 135a is not limited to the shapes of FIGS. 11A and 11B. For example, the shape of the first ridge 135a may be the shape exemplified in the second form.

The semiconductor material constituting the semiconductor laser element described so far may be a material other than the nitride semiconductor. The semiconductor material may be, for example, GaAs, InP, GaInP, GaInAsP, GaAlAs, or AlInGaP. In this case, the semiconductor material may be used as a semiconductor laser element having an oscillation wavelength of 760 nm or more and 1060 nm or less. In addition, the semiconductor laser element may be formed of materials other than these materials. For example, a semiconductor laser element that emits ultraviolet light may be configured using aluminum nitride, boron nitride, or the like.

### 2. Production Method

A method for manufacturing the semiconductor laser element L1 according to the present embodiment includes:
(i) a step of providing a substrate;
(ii) a step of forming a semiconductor layered portion and a diffraction grating;
(iii) a step of forming a ridge; and
(iv) a step of forming an electrode. Each semiconductor layer of the semiconductor layered portion can be formed by a method known in the art, such as a metal organic chemical vapor deposition (MOCVD) method, a halide vapor phase epitaxy (HVPE) method, a molecular beam epitaxy (MBE) method, or a sputtering method.

### (i) Step of Providing Substrate

First, a substrate 100 formed of GaN, for example, is provided. The substrate may be sapphire.

### (ii) Step of Forming Semiconductor Layered Portion and Diffraction Grating

Subsequently, as illustrated in FIG. 12, the n-side cladding layer 111 is formed on the substrate 100. The n-side cladding layer 111 may be formed after a base layer is provided on the substrate 100.

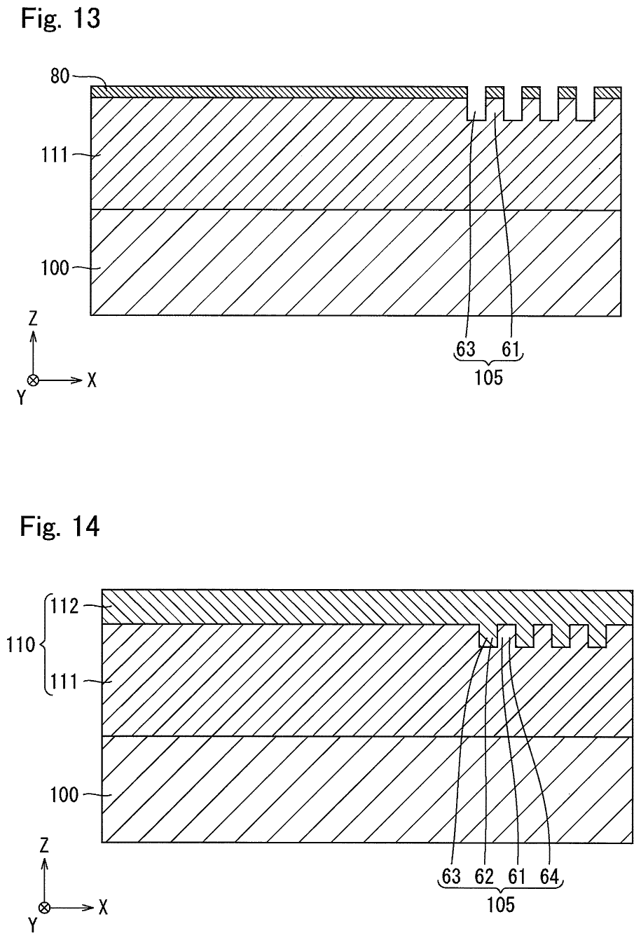

As a method of forming the first diffraction grating 105, the n-side cladding layer 111 is formed, and then a mask pattern 80 is formed as illustrated in FIG. 13. Examples of the method for forming the mask pattern 80 include a photolithography step and an etching step using a method known in the art such as a double resist method, an adhesion mask exposure method, an electron beam lithography method, and a phase shift method. The mask pattern 80 is preferably formed by an electron beam lithography method. An accurate mask pattern 80 is thus obtained. Subsequently, etching is performed using the mask pattern 80 as a mask to form the first recessed portion 63 and the first protrusion 61. Thereafter, as illustrated in FIG. 14, the mask pattern 80 is removed, and the first recessed portion 63 of the n-side cladding layer 111 can be formed by embedding the second protrusion 62 of the n-side light guide layer 112. Similarly, the second recessed portion 64 of the n-side light guide layer 112 is embedded in the first protrusion 61 of the n-side cladding layer 111. The pitch (that is, one cycle of the first recessed portion 63 and the first protrusion 61 or one cycle of the second protrusion 62 and the second recessed portion 64) of the first diffraction grating 105 is appropriately set according to a desired oscillation wavelength.

The mask pattern 80 in this case can be formed using various resists, a single-layer film or a multilayer film of an oxide or nitride such as Al₂O₃, ZrO₂, SiO₂, TiO₂, Ta₂O₅, AlN, or SiN, or a metal such as nickel or chromium. The film thickness thereof is preferably, for example, 10 nm or more and 500 nm or less. This makes it possible to form the first protrusion 61 and the second protrusion 62 at desired heights.

In addition, etching in a case where the semiconductor layer is etched using the mask pattern 80 to form the first protrusion 61 and the first recessed portion 63 is performed by dry etching such as reactive ion etching (RIE).

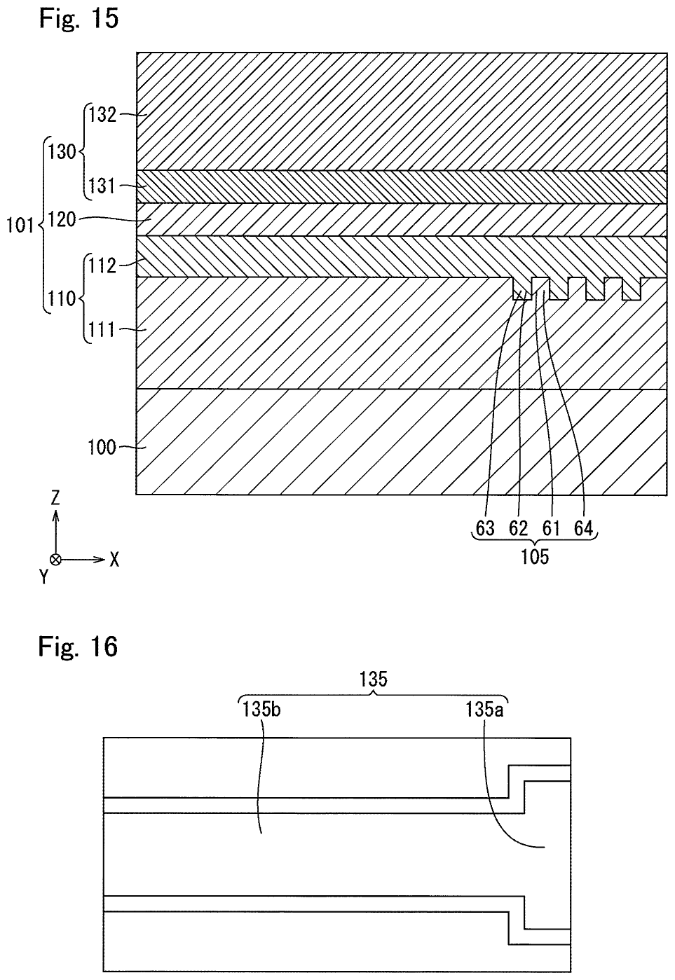

After the n-side light guide layer 112 is formed, as illustrated in FIG. 15, the active layer 120, the p-side light guide layer 131, and the p-side cladding layer 132 are sequentially formed on the n-side light guide layer 112 to provide the semiconductor layered portion 101.

When the active layer 120 has a multiple quantum well structure, barrier layers and well layers are alternately formed from the substrate 100 side by a desired number of layers to form the active layer 120. In this case, the step of forming the active layer 120 is completed by the step of forming the barrier layer. The active layer 120 may be a single quantum well layer.

(iii) Step of Forming Ridge

First, for example, a protective film formed of, for example, Si oxide (mainly SiO₂) is formed on substantially the entire surface of the p-side cladding layer 132 by, for example, a CVD method or a sputtering method, and then a mask is formed on the protective film in a region where the ridge 135 is formed. The protective film in the region where the mask is not formed is removed by RIE or the like to form a protective film having a shape corresponding to the ridge 135. Then, by etching the p-side cladding layer 132 using this protective film as a mask, the ridge 135 is formed as illustrated in FIG. 16. The ridge 135 is formed in the p-side cladding layer 132, for example. The ridge 135 may be formed by etching to the part of the p-side cladding layer 132, or may be formed by etching to the part of the p-side light guide layer 131.

### (iv) Step of Forming Electrode

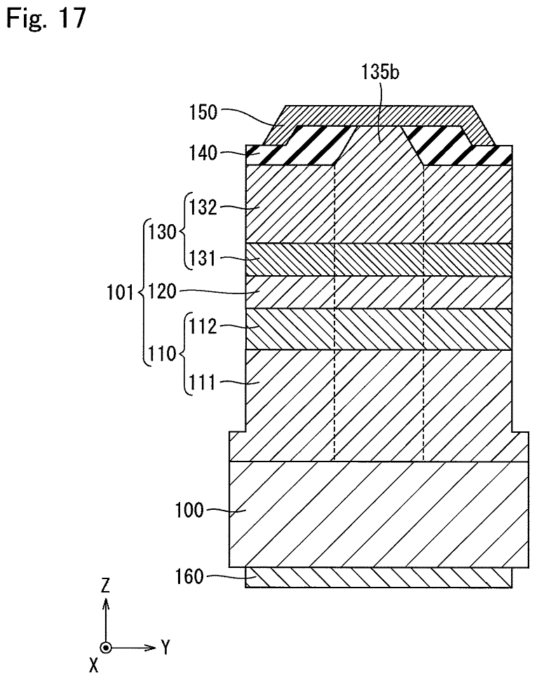

As illustrated in FIG. 17, the first electrode 150 is formed on an upper face of the ridge 135, and the second electrode 160 is formed on a lower face of the substrate 100.

The first electrode 150 is formed so as to be in contact with the upper face of the ridge 135. The insulating layer 140 is disposed on the upper face of the semiconductor layered portion 101 except for the upper surface of the ridge 135 so that the first electrode 150 is not in contact with the p-side semiconductor layer 130 except for the upper surface of the ridge 135. For example, after the insulating layer 140 is formed on the surface of the p-side cladding layer 132 except for the upper surface of the ridge 135, the first electrode 150 is formed on the upper face of the ridge 135 exposed from the insulating layer 140 by, for example, a sputtering method or the like. The first electrode 150 may be in contact with the lateral face of the ridge 135.

The second electrode 160 is disposed so as to be electrically connected to the n-side cladding layer 111. For example, when the substrate 100 has conductivity, the second electrode 160 can be formed on the lower face of the substrate 100. The second electrode 160 is formed by, for example, a sputtering method.

The first electrode 150 and the second electrode 160 can be formed using a method other than the sputtering method.

When the substrate 100 does not have conductivity, for example, the second electrode 160 may be formed directly on the exposed surface by exposing the surface of the n-side light guide layer 112 or the n-side cladding layer 111.

After the step of forming the electrode, the HR coating 220 is formed on the end face of the second region 2 on the side opposite to the first region 1, and the AR coating is formed on the end face of the first region 1 on the side opposite to the second region 2. The HR coating and the AR coating can be formed by, for example, vapor deposition, sputtering, or the like.

The semiconductor laser element L1 may be obtained by forming a plurality of semiconductor laser element portions on a wafer and then singulating the semiconductor laser element portions. The singulation may be performed by cleavage, laser scribing, or the like. When the end face of the second region 2 on the side opposite to the first region 1 is obtained by cleavage, the cleaved face may be used instead of the HR coating.

### First Modification of First Embodiment

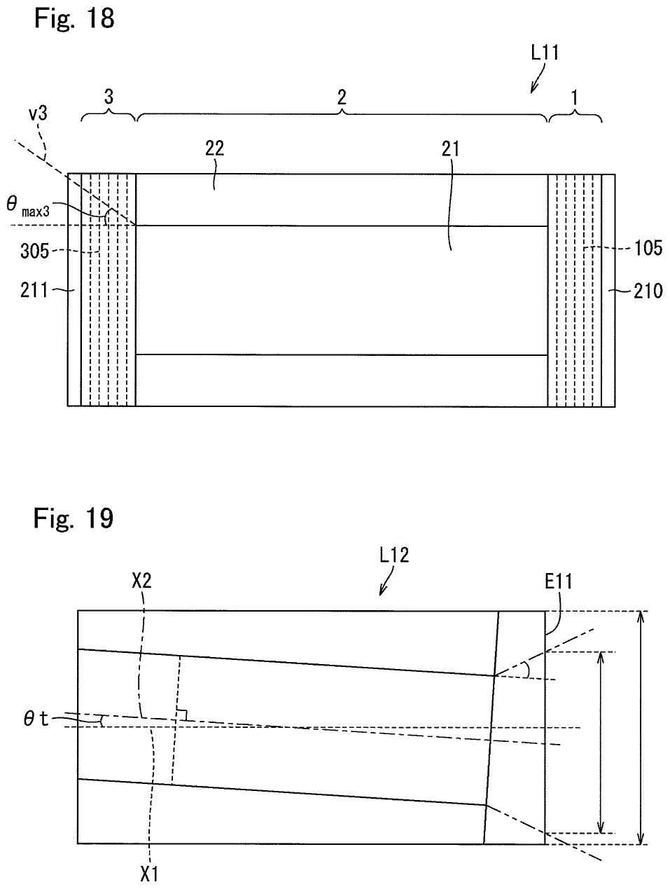

As illustrated in FIG. 18, the semiconductor laser element L11 according to the modification of the first embodiment is configured in the same manner as in the first embodiment except that the semiconductor layered portion 101 further includes a third region 3 that includes a second diffraction grating and has a refractive index n₃ on the opposite side of the first region 1 interposing the second region 2 therebetween.

The third region 3 is configured similarly to the first region 1. The definition of the refractive index n₃ is the same as the definition of the refractive index n₁.

Specifically, the laser beam emitted from the second region 2 to the third region 3 propagates through the third region at the maximum diffusion angle θₘₐₓ₃ determined by the refractive index n₃, the refractive index n₂₁, and the refractive index n₂₂, and in a cross section perpendicular to an optical axis of the laser beam, opposite end portions of the third region in a direction perpendicular to a stacking direction of the semiconductor layered portion are located outside the virtual lines v2 each extending at the maximum diffusion angle θₘₐₓ₃ from corresponding one of opposite ends of an emission end face (a second emission end face) of the first core region on the third region side.

The AR coating 211 is formed on the end face of the third region 3 on the opposite side of the second region 2, and in the semiconductor laser element L11 according to the modification, a laser beam is emitted from both the end face of the first region 1 and the end face of the third region 3. The laser beam may be selectively extracted from the first region side by making the reflectance of the laser beam in the first diffraction grating lower than the reflectance of the laser beam in the second diffraction grating. Alternatively, instead of the AR coating 211, an HR coating may be formed and the laser beam may be selectively extracted from the first region side.

### Second Modification of First Embodiment

As illustrated in FIG. 19, a semiconductor laser element L12 according to a modification of the first embodiment is different from the first embodiment in that the first end face E11 of the first region 1 from which the laser beam is output is inclined with respect to an optical axis X2 of the laser beam propagating through the first core region 21 and a periodic direction of the first diffraction grating 105.

The first end face E11 being inclined with respect to the optical axis X2 of the laser beam propagating through the first core region 21 and the periodic direction of the first diffraction grating 105 means that the first end face E11 is not orthogonal to both the optical axis X2 of the laser beam propagating through the first core region 21 and the periodic direction of the first diffraction grating 105. In this case, the optical axis X2 of the laser beam propagating through the first core region 21 coincides with the periodic direction of the first diffraction grating 105. That is, the optical axis X2 and the direction in which the first diffraction grating 105 extends are orthogonal to each other. On the other hand, the first end face E11 and the optical axis X2 are not orthogonal to each other.

As a result, it is possible to reduce the influence on the laser beam by the light reflected by the first end face E11 and re-incident on the first core region 21. In FIG. 19, an angle θt formed by the normal line X1 of the first end face E11 and the optical axis X2 may be 1 degree or more and 10 degrees or less.

### Third Embodiment

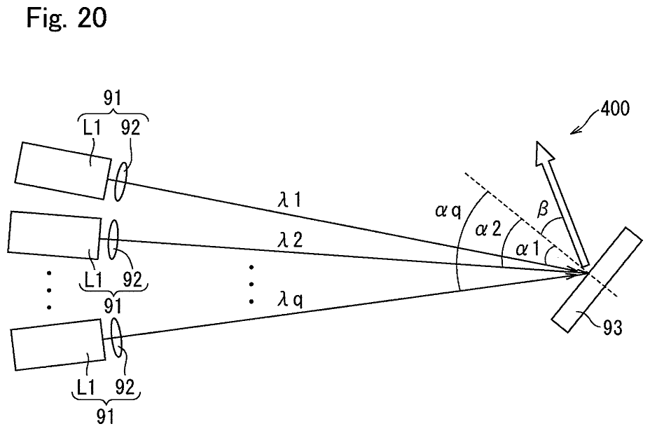

As illustrated in FIG. 20, the third embodiment relates to a wavelength beam combining (WBC) device 400 including a plurality of (q) semiconductor laser elements L1 according to the first embodiment. The WBC device 400 can irradiate the object to be processed with a laser beam having higher intensity, for example.

The WBC device 400 includes a plurality of light sources 91 and a multiplexing diffraction grating 93. Each of the plurality of light sources 91 includes the semiconductor laser element L1 of the first embodiment and a collimator lens 92. The oscillation wavelengths λ₁, λ₂, . . . , and λ_{q} of the semiconductor laser element L1 of each light source 91 are different from each other. The difference between the peak wavelengths of the oscillation wavelengths of the plurality of light sources 91 is, for example, 0.3 nm or more and 3 nm or less, preferably 0.4 nm or more and 1.5 nm or less, and more preferably 0.5 nm or more and 1 nm or less. As a result, the laser beam can be efficiently multiplexed in the band of the multiplexing diffraction grating 93. The semiconductor laser element L1 is a longitudinal multimode semiconductor laser, and the oscillation wavelength λ_{q} output from each light source 91 includes a plurality of oscillation wavelengths. However, the number of longitudinal modes may not coincide with each other at all the oscillation wavelengths λ_{q}. The collimator lens 92 is provided at a position where a laser beam emitted from the semiconductor laser element L1 is incident. The light source 91 does not need to include only a set of one semiconductor laser element L1 and one collimator lens 92, and may include a plurality of sets thereof. As a result, the output for the oscillation wavelength λ_{q} of each light source 91 can be increased.

The multiplexing diffraction grating 93 multiplexes the laser beam emitted from the plurality of light sources 91. The multiplexing diffraction grating 93 includes, for example, grooves and protrusions that are periodically provided. Each light source 91 is disposed such that a relationship between an incident angle a at which the laser beam having passed through the collimator lens 92 is incident on the multiplexing diffraction grating 93 and a diffraction angle β of the light diffracted by the multiplexing diffraction grating 93 satisfies the following Formula 4.

$$sin α + sin β = GI λ \qquad ( Formula 4 )$$

In Formula 4, G is the quantity of grooves (g/mm) of the diffraction grating of the multiplexing diffraction grating 93, 1 is the order, and λ is the oscillation wavelength (nm) of the laser beam emitted from the light source 91.

The oscillation wavelength λ_{q} output from each light source 91 includes a plurality of oscillation wavelengths, and the diffraction angle β corresponding to each oscillation wavelength is different. However, in the semiconductor laser element L1 included in the light source 91, the diffraction grating 60 is provided in the first region 1, and variation in oscillation wavelength is small. For example, the oscillation wavelength for each transverse mode is included in the range of the wavelength width of 0.01 nm or more and 0.6 nm or less. As a result, in each of the light sources 91, the shift of the diffraction angle β corresponding to the oscillation wavelength for each transverse mode is reduced. Therefore, the light emitted from each light source 91 can be multiplexed by the multiplexing diffraction grating 93 at substantially the same diffraction angle. As a result, the light emitted from the WBC device 400 has a high light output. The quantity of multiplexing diffraction gratings 93 is not limited to one. For example, there may be two multiplexing diffraction gratings 93: a first multiplexing diffraction grating and a second multiplexing diffraction grating. In this case, the first multiplexing diffraction grating diffracts the laser beams emitted from the plurality of light sources 91 and guides the laser beams to the second multiplexing diffraction grating. The second multiplexing diffraction grating diffracts and coaxially multiplexes the plurality of laser beams.

The light emitted from the WBC device 400 configured as described above is introduced into, for example, a multimode fiber. The core diameter of the multimode fiber is, for example, 90 μm or more and 400 μm or less.

### Example 1

A semiconductor laser element was manufactured, and the output of the laser beam was measured. The manufactured semiconductor laser element was obtained by stacking an n-side cladding layer, an n-side light guide layer, an active layer, a p-side light guide layer, and a p-side cladding layer on a GaN substrate. The first ridge and the second ridge were obtained by removing the p-side cladding layer and a part of the p-side light guide layer. The width of the first ridge was 350 μm, and the width of the second ridge was 90 μm. The diffraction grating was provided in the n-side semiconductor layer of the first region 1, and the period of the diffraction grating was 96 nm.

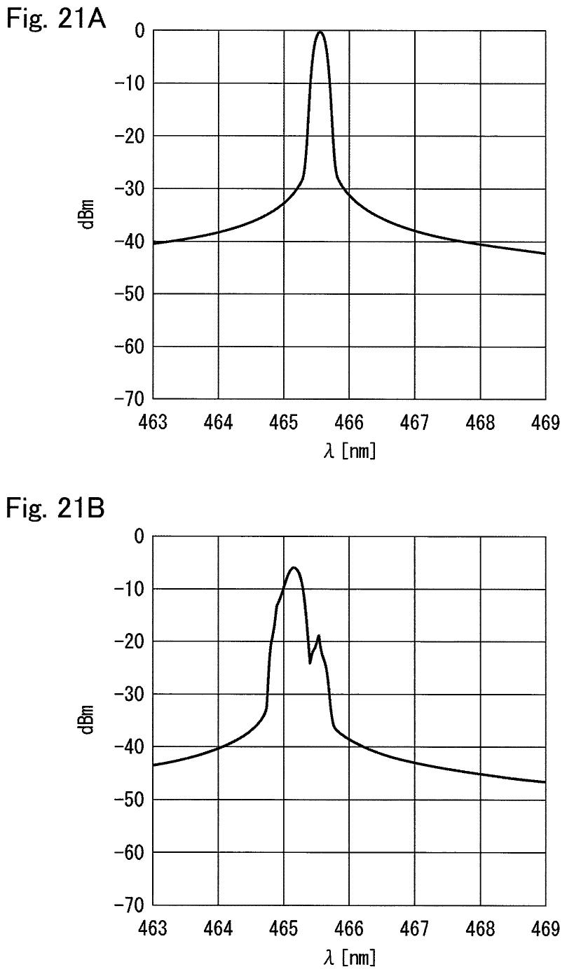

FIG. 21A is a graph illustrating intensity of the laser beam output from the semiconductor laser element when a current of 12A is supplied. The horizontal axis represents the wavelength (nm), and the vertical axis represents the intensity of the laser beam. However, the unit of the vertical axis is expressed in dBm. From FIG. 21A, the wavelength width at the position of 3 dBm, that is, the full width at half maximum was about 0.1 nm. The side mode suppression ratio was about 30 dBm. Although the semiconductor laser element is a transverse multimode semiconductor laser, the variation in wavelength could be reduced.

### Comparative Example 1

FIG. 21B is a graph showing the intensity of the laser beam output from the semiconductor laser element of Comparative Example 1 when a current of 12A is supplied. The semiconductor laser element of Comparative Example 1 is different from the semiconductor laser element of Example 1 in that a diffraction grating is formed on the entire surface of a transverse multimode waveguide having no first region and a ridge width of 90 μm. The diffraction grating was provided in the n-side semiconductor layer. From FIG. 21B, it was confirmed that the peak of Comparative Example 1 was loss in shape as compared with Example 1. That is, a peak was confirmed also outside the range of 3 dBm.

In Example 1, no peak disturbance was observed as compared with Comparative Example 1. This means that a large amount of power is concentrated within a wavelength width range of 3 dBm, and suggests that the semiconductor laser element of Example 1 can efficiently use the laser beam.

### Other Configurations

Furthermore, for example, the present disclosure can be configured as follows.

### (Clause 1)

A semiconductor laser element comprising a semiconductor layered portion including an active layer and having a waveguide structure, wherein
the semiconductor layered portion includes
(i) a first region that includes a first diffraction grating and has a refractive index n₁, and
(ii) a second region that includes a first core region having a refractive index n₂₁ and a first cladding region having a refractive index n₂₂ provided on opposite sides of the first core region, and propagates a laser beam in a plurality of transverse modes;
(iii) the laser beam emitted from the second region propagates through the first region at a maximum diffusion angle θₘₐₓ₁ determined by the refractive index n₁, the refractive index n₂₁, and the refractive index n₂₂; and
in a cross section perpendicular to an optical axis of the laser beam, opposite end portions of the first region in a direction perpendicular to a stacking direction of the semiconductor layered portion are each located outside a virtual line extending at the maximum diffusion angle θₘₐₓ₁ from opposite ends of an emission end face of the first core region on the first region side.

### (Clause 2)

A transverse multimode semiconductor laser element comprising: an active layer; and a semiconductor layered portion, wherein
the semiconductor layered portion includes
(i) a first region including a first diffraction grating, and
(ii) a second region that has a first core region and a first cladding region provided on opposite sides of the first core region, and propagates a laser beam in a plurality of transverse modes;
the first region has a first end face that emits the laser beam;
in a direction orthogonal to a stacking direction of the semiconductor layered portion of the first end face,
(iii) a width of the first end face is larger than a beam diameter of the laser beam; and
in top view,
(iv) in a direction orthogonal to a periodic direction of the first diffraction grating, the first region also expands in a direction away from a center of the laser beam with respect to a shorter line among lines connecting an end of the beam and a first vertex that is a boundary between the first region and a first core region of the second region.

### (Clause 3)

The semiconductor laser element according to Clause 1 or 2, wherein an interval between the end portions in the first diffraction grating is two times or more and 100 times or less a width of the first core region.

### (Clause 4)

The semiconductor laser element according to any one of Clauses 1 to 3, wherein
a width of the first core region is 15 μm or more and 90 μm or less; and
an interval between the ends of the first diffraction grating is 30 μm or more and 9,000 μm or less.

### (Clause 5)

The semiconductor laser element according to any one of Clauses 1 to 4, wherein an interval between the ends of the first diffraction grating is constant.

### (Clause 6)

The semiconductor laser element according to any one of Clauses 1 to 5, wherein a first end face of the first region from which the laser beam is output is inclined with respect to an optical axis of the laser beam propagating through the first core region and a periodic direction of the first diffraction grating.

### (Clause 7)

The semiconductor laser element according to any one of Clauses 1 to 6, wherein
the semiconductor layered portion includes an n-side semiconductor layer, a p-side semiconductor layer, and an active layer located between the n-side semiconductor layer and the p-side semiconductor layer; and
the first diffraction grating is provided in any one of the n-side semiconductor layer and the p-side semiconductor layer.

### (Clause 8)

The semiconductor laser element according to any one of Clauses 1 to 7, wherein a full width at half maximum of a spectral linewidth of the laser beam emitted from a first end face of the first region on which the laser beam emitted from the second region is incident, or a second end face opposite to the first end face is 0.01 nm or more and 0.6 nm or less.

### (Clause 9)

The semiconductor laser element according to any one of Clauses 1 to 8, wherein an M² factor of the laser beam is 2 or more and 100 or less.

### (Clause 10)

The semiconductor laser element according to any one of Clauses 1 to 9, wherein
the semiconductor layered portion
(iv) further includes a third region including a second diffraction grating and having a refractive index n₃ on an opposite side of the first region with the second region interposed therebetween;
(v) the laser beam emitted from the second region propagates through the third region at a maximum diffusion angle θₘₐₓ₃ determined by the refractive index n₃, the refractive index n₂₁, and the refractive index n₂₂; and
in a cross section perpendicular to an optical axis of the laser beam, opposite end portions of the third region in a direction perpendicular to a stacking direction of the semiconductor layered portion are each located outside a virtual line extending at the maximum diffusion angle θₘₐₓ₃ from opposite ends of an emission end face of the first core region on the third region side.

### (Clause 11)

A wavelength beam coupling device comprising
a plurality of light sources and
a diffraction grating,
wherein each of the plurality of light sources includes
the semiconductor laser element according to any one of Clauses 1 to 10 and
a collimator lens provided at a position where a laser beam emitted from the semiconductor laser element is incident;
a peak wavelength of the laser beam is different for each of the plurality of light sources; and
the diffraction grating multiplexes the laser beam emitted from the plurality of light sources.

Although the embodiments and the modifications of the present disclosure have been described above, various modifications can be made as long as the configuration is based on the technical idea of the present disclosure. In addition, various modifications can be made within the scope and spirit of the present disclosure to the combination and order of the components in the embodiments and the modifications.

What is claimed is:

1. A transverse multimode semiconductor laser element comprising:
a semiconductor layered portion that comprises an active layer and has a waveguide structure, wherein the semiconductor layered portion includes:
a first region that includes a first diffraction grating and has a refractive index n₁, and
a second region that includes a first core region having a refractive index n₂₁ and a plurality of first cladding regions having a refractive index n₂₂ respectively provided on opposite sides of the first core region, and allows a laser beam to propagate in a plurality of transverse modes; wherein:
the laser beam emitted from the second region propagates through the first region at a maximum diffusion angle θₘₐₓ₁ determined by the refractive index n₁, the refractive index n₂₁, and the refractive index n₂₂; and
in a cross section perpendicular to an optical axis of the laser beam, opposite end portions of the first region in a direction perpendicular to a stacking direction of the semiconductor layered portion are located outside virtual lines each extending at the maximum diffusion angle θₘₐₓ₁ from a corresponding one of opposite ends of a first emission end face of the first core region on the first region side.

2. The transverse multimode semiconductor laser element according to claim 1, wherein:
an interval between the end portions in the first diffraction grating is two times or more and 100 times or less a width of the first core region.

3. The transverse multimode semiconductor laser element according to claim 2, wherein:
a width of the first core region is 15 μm or more and 100 μm or less; and
an interval between the ends of the first diffraction grating is 30 μm or more and 9,000 μm or less.

4. The transverse multimode semiconductor laser element according to claim 1, wherein:
an interval between the ends of the first diffraction grating is constant.

5. The transverse multimode semiconductor laser element according to claim 2, wherein:
an interval between the ends of the first diffraction grating is constant.

6. The transverse multimode semiconductor laser element according to claim 3, wherein:
an interval between the ends of the first diffraction grating is constant.

7. The transverse multimode semiconductor laser element according to claim 1, wherein:
a first end face of the first region from which the laser beam is output is inclined with respect to an optical axis of the laser beam propagating through the first core region and a periodic direction of the first diffraction grating.

8. The transverse multimode semiconductor laser element according to claim 1, wherein:
the semiconductor layered portion further comprises an n-side semiconductor layer, a p-side semiconductor layer;
the active layer is located between the n-side semiconductor layer and the p-side semiconductor layer; and
the first diffraction grating is provided in the n-side semiconductor layer or the p-side semiconductor layer.

9. The transverse multimode semiconductor laser element according to claim 1, wherein:
a full width at half maximum of a spectral linewidth of the laser beam emitted from a first end face of the first region on which the laser beam emitted from the second region is incident, or a second end face opposite to the first end face, is 0.01 nm or more and 0.6 nm or less.

10. The transverse multimode semiconductor laser element according to claim 6, wherein:
a full width at half maximum of a spectral linewidth of the laser beam emitted from a first end face of the first region on which the laser beam emitted from the second region is incident, or a second end face opposite to the first end face, is 0.01 nm or more and 0.6 nm or less.

11. The transverse multimode semiconductor laser element according to claim 1, wherein:
an M² factor of the laser beam is 2 or more and 100 or less.

12. The transverse multimode semiconductor laser element according to claim 6, wherein:
an M² factor of the laser beam is 2 or more and 100 or less.

13. The transverse multimode semiconductor laser element according to claim 10, wherein:
an M² factor of the laser beam is 2 or more and 100 or less.

14. The transverse multimode semiconductor laser element according to claim 1, wherein:
the semiconductor layered portion further includes a third region comprising a second diffraction grating and having a refractive index n₃, the third region being on a side opposite the first region such that the second region is interposed between the first region and the third region;
the laser beam emitted from the second region propagates through the third region at a maximum diffusion angle θₘₐₓ₃ determined by the refractive index n₃, the refractive index n₂₁, and the refractive index n₂₂; and
in a cross section perpendicular to an optical axis of the laser beam, opposite end portions of the third region in a direction perpendicular to a stacking direction of the semiconductor layered portion are located outside virtual lines each extending at the maximum diffusion angle θₘₐₓ₃ from a corresponding one of opposite ends of a second emission end face of the first core region on the third region side.

15. A transverse multimode semiconductor laser element comprising:
a semiconductor layered portion comprising an active layer, the semiconductor layered portion comprising:
a first region comprising a first diffraction grating, and
a second region that has a first core region and a plurality of first cladding regions respectively provided on opposite sides of the first core region, and allows a laser beam to propagate in a plurality of transverse modes; wherein:
the first region has a first end face that emits the laser beam;
in a direction orthogonal to a stacking direction of the semiconductor layered portion, a width of the first end face is larger than a beam diameter of the laser beam; and
in top view, in a direction orthogonal to a periodic direction of the first diffraction grating, the first region expands in a direction away from a center of the laser beam with respect to a shorter line among lines connecting an end of the beam and a first vertex that is a boundary between the first region and the first core region of the second region.

16. A transverse multimode semiconductor laser element comprising:
a semiconductor layered portion comprising an active layer, the semiconductor layered portion comprising:
a first region comprising a first diffraction grating, and
a second region having a transverse multimode waveguide; wherein:
the first region comprises a first ridge having a first end face on a side where the laser beam is emitted, and second end faces and on a side opposite to the first end face;
the second region comprises a second ridge having a first lateral face and a second lateral face opposite to the first lateral face; and
in a cross-sectional view orthogonal to a periodic direction of the first diffraction grating:
a width of the first end face in a direction orthogonal to the stacking direction of the semiconductor layered portion is larger than a beam diameter of the laser beam, and
an angle formed by the second end face and the first lateral face and an angle formed by the second end face and the second lateral face are each 30° or more and 120° or less.

17. A wavelength beam coupling device comprising
a plurality of light sources; and
a diffraction grating; wherein:
each of the plurality of light sources comprises:
the transverse multimode semiconductor laser element according to claim 1, and
a collimator lens located at a position where a laser beam emitted from the semiconductor laser element is incident;
a peak wavelength of the laser beam is different for each of the plurality of light sources; and
the diffraction grating is configured to multiplex the laser beam emitted from the plurality of light sources.

18. A wavelength beam coupling device comprising
a plurality of light sources; and
a diffraction grating; wherein:
each of the plurality of light sources comprises:
the transverse multimode semiconductor laser element according to claim 15, and
a collimator lens located at a position where a laser beam emitted from the semiconductor laser element is incident;
a peak wavelength of the laser beam is different for each of the plurality of light sources; and
the diffraction grating is configured to multiplex the laser beam emitted from the plurality of light sources.

19. A wavelength beam coupling device comprising:
a plurality of light sources; and
a diffraction grating; wherein:
each of the plurality of light sources comprises:
the transverse multimode semiconductor laser element according to claim 16, and
a collimator lens located at a position where a laser beam emitted from the semiconductor laser element is incident;
a peak wavelength of the laser beam is different for each of the plurality of light sources; and
the diffraction grating is configured to multiplex the laser beam emitted from the plurality of light sources.
